(19) United States
(12) Patent Application Publication
(10) Pub. No.: US 2026/0206456 A1
(43) Pub. Date: Jul. 16, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventor: CHUNGI YOU, Yongin-si (KR)

(21) Appl. No.: 19/375,501

(22) Filed: Oct. 31, 2025

(30) Foreign Application Priority Data
Jan. 13, 2025 (KR) 10-2025-0004631

(51) Int. Cl. H10K 59/80; H10K 59/12; H10K 59/124

(52) U.S. Cl. CPC H10K 59/80515; H10K 59/1201; H10K 59/124

(57) ABSTRACT

A display device includes: a transistor array substrate; a first pixel electrode on the transistor array substrate, and including a first reflective electrode, a first thickness compensation layer, and a first transparent electrode; a second pixel electrode on the transistor array substrate, and including a second reflective electrode, a second thickness compensation layer, and a second transparent electrode; a third pixel electrode on the transistor array substrate, and including a third reflective electrode and a third transparent electrode; a planarization layer having first openings overlapping with the first pixel electrode, the second pixel electrode, and the third pixel electrode; a light-emitting layer on the first pixel electrode, the second pixel electrode, and the third pixel electrode; and a common electrode on the light-emitting layer. A thickness of the first thickness compensation layer is greater than a thickness of the second thickness compensation layer.

### CROSS-REFERENCE TO RELATED APPLICATION

The present application claims priority to and the benefit of Korean Patent Application No. 10-2025-0004631, filed on Jan. 13, 2025, in the Korean Intellectual Property Office, the entire disclosure of which is incorporated by reference herein.

### BACKGROUND

### 1. Field

Aspects of embodiments of the present disclosure relate to a display device that provides visual information, a method of manufacturing the display device, and an electronic device including the display device.

### 2. Description of the Related Art

As an applicability of a display device diversifies, interest continues in large display devices, such as large televisions, in-vehicle displays, and smartphones. The display device may include a light-emitting element that emits light. The light-emitting element may include a light-emitting layer that emits light, and an anode and a cathode laminated while disposing the light-emitting layer between the anode and the cathode.

However, as intensive research on an enlargement of recently developed display devices is underway, technologies for a luminance uniformity and a luminance enhancement are being developed. In particular, as one of the technologies for improving a luminance, research is being conducted on a technique for amplifying an intensity of light emitted from the light-emitting element by inducing a constructive interference between the light emitted from the light-emitting layer and the light reflected from the anode.

The above information disclosed in this Background section is for enhancement of understanding of the background of the present disclosure, and therefore, it may contain information that does not constitute prior art.

### SUMMARY

One or more embodiments of the present disclosure may be directed to a display device having an improved display quality.

One or more embodiments of the present disclosure may be directed to a method of manufacturing the display device.

One or more embodiments of the present disclosure may be directed to an electronic device including the display device.

According to one or more embodiments of the present disclosure, a display device includes: a transistor array substrate including: a display area including a first light-emitting area, a second light-emitting area, and a third light-emitting area spaced from each other; and; a non-display area adjacent to the display area; a first pixel electrode in the first light-emitting area on the transistor array substrate, and including a sequential stack of a first reflective electrode, a first thickness compensation layer, and a first transparent electrode; a second pixel electrode in the second light-emitting area on the transistor array substrate, and including a sequential stack of a second reflective electrode, a second thickness compensation layer, and a second transparent electrode; a third pixel electrode in the third light-emitting area on the transistor array substrate, and including a sequential stack of a third reflective electrode and a third transparent electrode; a planarization layer having first openings overlapping with the first pixel electrode, the second pixel electrode, and the third pixel electrode; a light-emitting layer on the first pixel electrode, the second pixel electrode, and the third pixel electrode; and a common electrode on the light-emitting layer. A thickness of the first thickness compensation layer is greater than a thickness of the second thickness compensation layer.

In an embodiment, the planarization layer may include: a first planarization portion located between the first pixel electrode and the second pixel electrode; and a second planarization portion located between the second pixel electrode and the third pixel electrode. The first planarization portion and the second planarization portion may have an equal height as each other.

In an embodiment, the first thickness compensation layer may include a sequential stack of a first-first thickness compensation layer and a first-second thickness compensation layer. A thickness of one compensation layer among the first-first thickness compensation layer or the first-second thickness compensation layer may be equal to a thickness of the second thickness compensation layer.

In an embodiment, the first-first thickness compensation layer and the first-second thickness compensation layer may include a same material as each other.

In an embodiment, the first-first thickness compensation layer and the first-second thickness compensation layer may include a different material from each other.

In an embodiment, the third pixel electrode may further include a dummy pattern on an edge portion of the third reflective electrode between the third reflective electrode and the third transparent electrode.

In an embodiment, a thickness of the dummy pattern and a thickness of the second thickness compensation layer may be equal to each other.

In an embodiment, the first thickness compensation layer may include at least one selected from an oxide group consisting of a silicon oxide (SiOₓ), a silicon nitride (SiNₓ), a silicon oxynitride (SiOₓN_{y}), an aluminum oxide (Al₂O₃), a titanium oxide (TiO₂), a tantalum oxide (Ta₂O₅), a hafnium oxide (HfO₂), a zinc oxide (ZrO₂), a TEOS (tetraethyl orthosilicate), and a FTEOS (fluorinate tetraethyl orthosilicate).

In an embodiment, the first transparent electrode may cover an upper surface of the first thickness compensation layer, a side surface of the first thickness compensation layer, and a side surface of the first reflective electrode. The second transparent electrode may cover an upper surface of the second thickness compensation layer, a side surface of the second thickness compensation layer, and a side surface of the second reflective electrode.

In an embodiment, a center portion of an upper surface of the first transparent electrode may have a first height with respect to the transistor array substrate, a center portion of an upper surface of the second transparent electrode may have a second height less than the first height with respect to the transistor array substrate, and a center portion of an upper surface of the third transparent electrode may have a third height less than the second height with respect to the transistor array substrate.

In an embodiment, the display device may further include: a capping structure surrounding around the first pixel electrode, the second pixel electrode, and third pixel electrode between the first pixel electrode, the second pixel electrode, and the third pixel electrode and the planarization layer. Second openings overlapping with first pixel electrode, the second pixel electrode, and the third pixel electrode may penetrate the capping structure.

In an embodiment, the third pixel electrode may further include a dummy pattern at an edge portion of the third reflective electrode between the third reflective electrode and the third transparent electrode, and the dummy pattern may not overlap with the second openings.

In an embodiment, a first distance between the first reflective electrode and the common electrode may be greater than a second distance between the second reflective electrode and the common electrode, and the second distance may be greater than a third distance between the third reflective electrode and the common electrode.

According to one or more embodiments of the present disclosure, a method of manufacturing a display device includes: providing a transistor array substrate including: a display area including a first light-emitting area, a second light-emitting area, and a third light-emitting area spaced from each other; and a non-display area adjacent to the display area; forming a first reflective electrode, a second reflective electrode, and a third reflective electrode in the first light-emitting area, the second light-emitting area, and third light-emitting area on the transistor array substrate, respectively; forming a first thickness compensation layer and a second thickness compensation layer in the first light-emitting area and second light-emitting area, respectively, on the first reflective electrode and the second reflective electrode; forming a first transparent electrode on the first thickness compensation layer in the first light-emitting area; forming a second transparent electrode on the second thickness compensation layer in the second light-emitting area; forming a third transparent electrode on the third reflective electrode in the third light-emitting area; forming a planarization layer having openings overlapping with the first transparent electrode, the second transparent electrode, and third transparent electrode on the transistor array substrate; forming a light-emitting layer in the first light-emitting area, the second light-emitting area, and the third light-emitting area on the first transparent electrode, the second transparent electrode, and the third transparent electrode; and forming a common electrode in the first light-emitting area, the second light-emitting area, and the third light-emitting area on the light-emitting layer. A thickness of the first thickness compensation layer is greater than a thickness of the second thickness compensation layer.

In an embodiment, the forming of the first thickness compensation layer and the second thickness compensation layer may include: forming a reflective electrode layer on the transistor array substrate; forming a preliminary thickness compensation layer in the first light-emitting area, the second light-emitting area, and the third light-emitting area on the reflective electrode layer; and forming the second thickness compensation layer in the second light-emitting area by removing a portion of the preliminary thickness compensation layer.

In an embodiment, the first thickness compensation layer may include a first-first thickness compensation layer and a first-second thickness compensation layer sequentially stacked, and the forming of the first thickness compensation layer and the second thickness compensation layer may include: forming the first-second thickness compensation layer on the preliminary thickness compensation layer in the first light-emitting area; and forming the first-first thickness compensation layer under the first-second thickness compensation layer by removing the portion of the preliminary thickness compensation layer.

In an embodiment, the first thickness compensation layer may include a first-first thickness compensation layer and a first-second thickness compensation layer sequentially stacked, and the forming of the first thickness compensation layer and the second thickness compensation layer may include: forming the first-first thickness compensation layer in the first light-emitting area on the reflective electrode layer before forming the preliminary thickness compensation layer; and forming the first-second thickness compensation layer on the first-first thickness compensation layer by removing the portion of the preliminary thickness compensation layer.

In an embodiment, the forming of the third transparent electrode may include: forming a third thickness compensation layer on the third reflective electrode by removing the portion of the preliminary thickness compensation layer; forming a dummy pattern at an edge portion of the third reflective electrode by removing a portion of the third thickness compensation layer; and forming the third transparent electrode surrounding around the third reflective electrode and the dummy pattern.

In an embodiment, the forming of the planarization layer may include: forming a first capping structure covering the first transparent electrode; forming a second capping structure covering the second transparent electrode; forming a third capping structure covering the third transparent electrode; forming a preliminary planarization layer on the first capping structure, the second capping structure, and the third capping structure; exposing an upper surface of the first capping structure by planarizing the preliminary planarization layer; and forming the openings overlapping with the first transparent electrode, the second transparent electrode, and the third transparent electrode in the preliminary planarization layer.

According to one or more embodiments of the present disclosure, an electronic device includes: a processor configured to output an image data signal and an input control signal; and a display device configured to process the image data signal and the input control signal to output image information through a display screen, the display device including: a transistor array substrate including: a display area including: a first light-emitting area, a second light-emitting area, and a third light-emitting area spaced from each other; and a non-display area adjacent to the display area; a first pixel electrode in the first light-emitting area on the transistor array substrate, and including a sequential stack of a first reflective electrode, a first thickness compensation layer, and a first transparent electrode; a second pixel electrode in the second light-emitting area on the transistor array substrate, and including a sequential stack of a second reflective electrode, a second thickness compensation layer, and a second transparent electrode; a third pixel electrode in the third light-emitting area on the transistor array substrate, and including a sequential stack of a third reflective electrode and a third transparent electrode; a planarization layer having first openings overlapping with the first pixel electrode, the second pixel electrode, and the third pixel electrode; a light-emitting layer on the first pixel electrode, the second pixel electrode, and the third pixel electrode; and a common electrode on the light-emitting layer. A thickness of the first thickness compensation layer is greater than a thickness of the second thickness compensation layer.

According to some embodiments of the present disclosure, in a first light-emitting area of a display device, a first pixel electrode may include two thickness compensation layers, and in a second light-emitting area of the display device, a second pixel electrode may include one thickness compensation layer. Accordingly, a resonant distance, at which a constructive interference may be generated for each light of a first color, light of a second color, and light of a third color emitted from a light-emitting layer, may be secured (e.g., may be easily secured). Therefore, because an implementation rate of the light of the first color, the light of the second color, and the light of the third color of the display device may be improved, a display quality of the display device may be improved.

According to some embodiments of the present disclosure, in a method of manufacturing the display device, in the first light-emitting area, a preliminary thickness compensation layer may be removed so that two thickness compensation layers remain, and in the second light-emitting area, the preliminary thickness compensation layer may be removed so that one thickness compensation layer remains. In a third light-emitting area, a dummy pattern in which a recess portion is defined may be formed. In addition, a planarization layer having an equal or substantially equal height (e.g., the same or substantially the same height) from the transistor array substrate may be formed between the first light-emitting area, the second light-emitting area, and the third light-emitting area. Accordingly, the display device having an improved display quality may be manufactured (e.g., may be easily manufactured), and time and costs in a manufacturing process of the display device may be reduced.

According to some embodiments of the present disclosure, an electronic device may include the display device having an improved display quality and operates stably.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a plan view illustrating a display device according to an embodiment of the present disclosure.

FIG. 2 is a circuit diagram illustrating a first pixel included in the display device of FIG. 1.

FIG. 3 is a cross-sectional view taken along the line I-I′ of FIG. 1.

FIGS. 4-17 are views illustrating a method of manufacturing the display device of FIG. 1.

FIG. 18 is a block diagram of an electronic device according to an embodiment.

FIG. 19 is schematic diagrams of the electronic device of FIG. 18 according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present disclosure described herein (e.g., the various units and modules) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

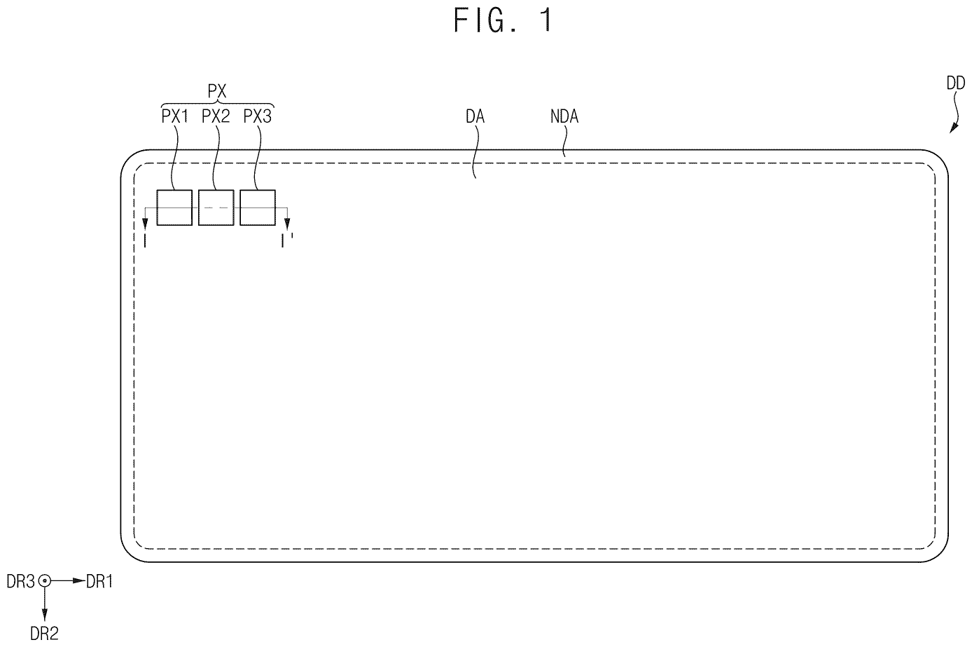

FIG. 1 is a plan view illustrating a display device according to an embodiment of the present disclosure.

Referring to FIG. 1, a display device DD according to an embodiment of the present disclosure may include a display area DA and a non-display area NDA. The display area DA may be defined as an area that generates images, and the non-display area NDA may be defined as an area that does not generate images.

As used herein, a plane may be defined by a first direction DR1, and a second direction DR2 crossing the first direction DR1. For example, the second direction DR2 may be perpendicular to or substantially perpendicular to the first direction DR1. In addition, a third direction DR3 may be perpendicular to or substantially perpendicular to the plane.

At least one pixel PX may be arranged in the display area DA. The pixel PX may include a first pixel PX1, a second pixel PX2, and a third pixel PX3. For example, light of a first color may be visible from the first pixel PX1, light of a second color may be visible from the second pixel PX2, and light of a third color may be visible from the third pixel PX3. In an embodiment, the light of the first color may be a red light, the light of the second color may be a green light, and the light of the third color may be a blue light. However, the present disclosure is not limited thereto. For example, the pixel PX may emit a yellow light, a cyan light, and a magenta light.

The first, second, and third pixels PX1, PX2, PX3 may be repeatedly arranged in a plan view along the first direction DR1 and the second direction DR2. For example, the second pixel PX2 may be located in the first direction DR1 from the first pixel PX1. In addition, the third pixel PX3 may be located in the first direction DR1 from the second pixel PX2.

The non-display area NDA may be located around the display area DA. For example, the non-display area NDA may surround (e.g., around a periphery of) at least a portion of the display area DA. A driver may be arranged in the non-display area NDA. The driver may provide a signal or a voltage to the pixel PX. For example, the driver may include a data driver, a gate driver, a power voltage generator, a driving controller, and the like. However, the present disclosure is not limited thereto, and components (e.g., the first pixel PX1, the second pixel PX2, and the third pixel PX3) that emit light may be arranged in the non-display area NDA.

In an embodiment, the display device DD may be a micro light-emitting diode display device including micro light-emitting diodes as light-emitting elements. However, the present disclosure is not limited thereto, and the display device DD may be an organic light-emitting diode display device including organic light-emitting diodes as light-emitting elements, or a quantum dot light-emitting display device including quantum dots as light-emitting elements.

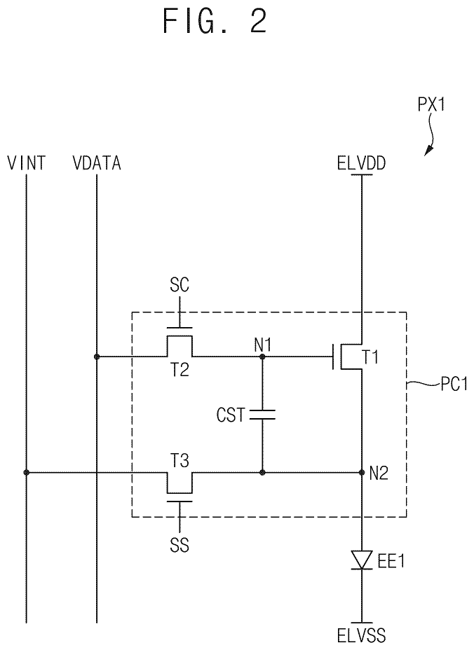

FIG. 2 is a circuit diagram illustrating a first pixel included in the display device of FIG. 1.

Referring to FIG. 2, the first pixel PX1 may include a first pixel circuit portion PC1, and a first light-emitting element EE1 electrically connected to the first pixel circuit portion PC1. The first pixel circuit portion PC1 may include a first transistor T1, a second transistor T2, a third transistor T3, and a storage capacitor CST.

The first transistor T1 may include a first electrode, a gate electrode, and a second electrode. The gate electrode of the first transistor T1 may be connected to a first node N1. A first power voltage ELVDD may be applied to the first electrode of the first transistor T1. The second electrode of the first transistor T1 may be connected to a second node N2. The first transistor T1 may generate a driving current based on a voltage between the first node N1 and the second node N2, or in other words, a voltage stored in the storage capacitor CST. The first transistor T1 may be referred to as a driving transistor for generating the driving current. The first transistor T1 may provide the driving current to the first light-emitting element EE1.

The second transistor T2 may include a first electrode, a gate electrode, and a second electrode. A first scan signal SC may be applied to the gate electrode of the second transistor T2. A data voltage VDATA may be applied to the first electrode of the second transistor T2. The second electrode of the second transistor T2 may be connected to the first node N1. The second transistor T2 may be turned on by the first scan signal SC to electrically connect a data voltage line providing the data voltage VDATA to the first node N1. The second transistor T2 may be referred to as a write transistor or a scan transistor for delivering the data voltage VDATA.

The third transistor T3 may include a first electrode, a gate electrode, and a second electrode. A second scan signal SS may be applied to the gate electrode of the third transistor T3. An initialization voltage VINT may be applied to the first electrode of the third transistor T3. The second electrode of the third transistor T3 may be connected to the second node N2. The third transistor T3 may be turned on by the second scan signal SS to electrically connect an initialization voltage line providing the initialization voltage VINT to the second node N2. The third transistor T3 may be referred to as an initialization transistor.

The storage capacitor CST may include a first electrode and a second electrode. The first electrode of the storage capacitor CST may be connected to the first node N1. The second electrode of the storage capacitor CST may be connected to the second node N2. The storage capacitor CST may store a difference voltage between the gate voltage and the source voltage of the first transistor T1.

The first light-emitting element EE1 may include a first terminal (e.g., an anode terminal) and a second terminal (e.g., a cathode terminal). The first terminal of the first light-emitting element EE1 may be connected to the second node N2, and the second terminal may be supplied with a second power voltage ELVSS. The first light-emitting element EE1 may generate light having a luminance corresponding to the driving current. In an embodiment, the first light-emitting element EE1 may emit light of the first color.

In an embodiment, the second power voltage ELVSS may have a voltage level different from that of the first power voltage ELVDD. For example, a voltage level of the second power voltage ELVSS may be lower than a voltage level of the first power voltage ELVDD. In more detail, the voltage level may refer to a magnitude of the voltage. However, the relationship between the voltage levels of the second power voltage ELVSS and the first power voltage ELVDD according to embodiments of the present disclosure is not limited thereto.

In an embodiment, each of the first, second, and third transistors T1, T2, and T3 may be n-type transistors. However, the types of the first, second, and third transistors T1, T2, and T3 according to embodiments of the present disclosure is not limited thereto, and at least one of the first second, and/or third transistors T1, T2, and/or T3 may be a p-type transistor.

In FIG. 2, the number of transistors included in the first pixel PX1 is illustrated as four and the number of capacitors as one, but the numbers of transistors and capacitors included in the pixel according to embodiments of the present disclosure is not limited thereto. For example, the first pixel PX1 may include three or fewer transistors or five or more transistors, and/or a single first pixel PX1 may include two or more capacitors.

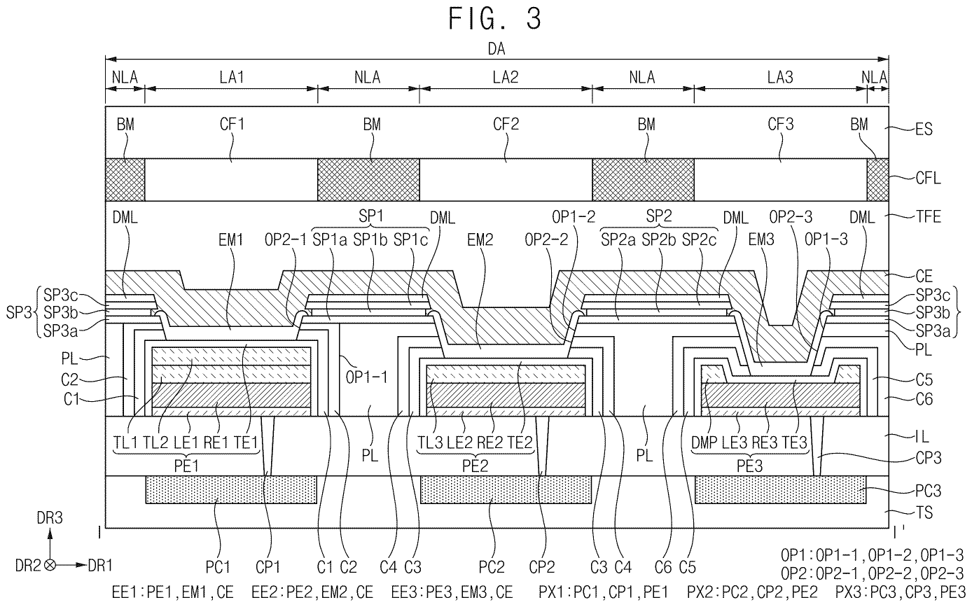

Although the circuit structure of the first pixel PX1 is illustrated in FIG. 2, the second pixel PX2 and the third pixel PX3 may each have the same or substantially the same circuit structure as that of the first pixel PX1. For example, the second pixel PX2 may include a second light-emitting element (e.g., a second light-emitting element EE2 in FIG. 3) that emits light of the second color, and a second pixel circuit portion (e.g., a second pixel circuit portion PC2 in FIG. 3) electrically connected to the second light-emitting element. For example, the third pixel PX3 may include a third light-emitting element (e.g., a third light-emitting element EE3 in FIG. 3) that emits light of the third color, and a third pixel circuit portion (e.g., a third pixel circuit portion PC3 in FIG. 3) electrically connected to the third light-emitting element.

FIG. 3 is a cross-sectional view taken along the line I-I′ of FIG. 1.

Referring to FIG. 3, the display area DA may include a first light-emitting area LA1, a second light-emitting area LA2, a third light-emitting area LA3, and a non-light-emitting area NLA. The first light-emitting area LA1 may include the first pixel PX1 that emits light of the first color. The second light-emitting area LA2 may include the second pixel PX2 that emits light of the second color. The third light-emitting area LA3 may include the third pixel PX3 that emits light of the third color. In other words, the first, second, and third light-emitting areas LA1, LA2, and LA3 may be areas in which light is emitted within the display area DA.

The non-light-emitting area NLA may be located between two adjacent light-emitting areas among the first light-emitting area LA1, the second light-emitting area LA2, and the third light-emitting area LA3. For example, one non-light-emitting area NLA may be located between the first light-emitting area LA1 and the second light-emitting area LA2. As another example, one non-light-emitting area NLA may be located between the second light-emitting area LA2 and the third light-emitting area LA3. As another example, one non-light-emitting area NLA may be located between the first light-emitting area LA1 and the third light-emitting area LA3. The non-light-emitting area NLA may be an area in which light is not emitted within the display area DA.

In an embodiment, the first, second, and third light-emitting areas LA1, LA2, and LA3 may have the same or substantially the same area as each other. However, the present disclosure is not limited thereto, and the first, second, and third light-emitting areas LA1, LA2, and LA3 may have different areas from each other.

The display device DD may include a transistor array substrate TS, an insulating structure IL, a first connection portion CP1, a second connection portion CP2, a third connection portion CP3, a first light-emitting element EE1, a second light-emitting element EE2, a third light-emitting element EE3, a first capping layer C1, a second capping layer C2, a third capping layer C3, a fourth capping layer C4, a fifth capping layer C5, a sixth capping layer C6, a planarization layer PL, a first separation structure SP1, a second separation structure SP2, a third separation structure SP3, dummy layers DML, a thin film encapsulation layer TFE, a color filter layer CFL, and an encapsulation substrate ES.

The transistor array substrate TS may include a first pixel circuit portion PC1, a second pixel circuit portion PC2, and a third pixel circuit portion PC3. The first pixel circuit portion PC1, the first connection portion CP1, and the first pixel electrode PE1 may define the first pixel PX1. The second pixel circuit portion PC2, the second connection portion CP2, and the second pixel electrode PE2 may define the second pixel PX2. The third pixel circuit portion PC3, the third connection portion CP3, and the third pixel electrode PE3 may define the third pixel PX3.

The first light-emitting element EE1 may include the first pixel electrode PE1, a first light-emitting layer EM1, and a common electrode CE. The first pixel electrode PE1 may include a first lower electrode LE1, a first reflective electrode RE1, a first thickness compensation layer TL1, a second thickness compensation layer TL2, and a first transparent electrode TE1.

The second light-emitting element EE2 may include the second pixel electrode PE2, a second light-emitting layer EM2, and the common electrode CE. The second pixel electrode PE2 may include a second lower electrode LE2, a second reflective electrode RE2, a third thickness compensation layer TL3, and a second transparent electrode TE2.

The third light-emitting element EE3 may include the third pixel electrode PE3, a third light-emitting layer EM3, and the common electrode CE. The third pixel electrode PE3 may include a third lower electrode LE3, a third reflective electrode RE3, a dummy pattern DMP, and a third transparent electrode TE3.

The first capping layer C1 and the second capping layer C2 may be collectively referred to as a first capping structure. The third capping layer C3 and the fourth capping layer C4 may be collectively referred to as a second capping structure. The fifth capping layer C5 and the sixth capping layer C6 may be collectively referred to as a third capping structure. As another example, the first, second, third, fourth, fifth, and sixth capping layers C1, C2, C3, C4, C5, and C6 may be collectively referred to as a capping structure.

The first thickness compensation layer TL1 and the second thickness compensation layer TL2 may be collectively referred to as a first thickness compensation layer, and the third thickness compensation layer TL3 may be referred to as a second thickness compensation layer. In addition, the first thickness compensation layer TL1 may be referred to as a first-first thickness compensation layer, and the second thickness compensation layer TL2 may be referred to as a first-second thickness compensation layer.

The first, second, and third light-emitting layers EM1, EM2, and EM3 may be referred to as a light-emitting layer.

The transistor array substrate TS may form a base of the display device. In an embodiment, the transistor array substrate TS may be a semiconductor circuit substrate. In an embodiment, the transistor array substrate TS may include a silicon wafer. However, the present disclosure is not limited thereto, and the transistor array substrate TS may include glass, quartz, plastic, and/or the like.

Each of the first, second, and third pixel circuit portions PC1, PC2, and PC3 may be a portion of a doped transistor array substrate TS. Each of the first, second, and third pixel circuit portions PC1, PC2, and PC3 may include a source area, a drain area, and a well area located between the source area and the drain area.

For example, the well area may be a channel of at least one transistor included in each of the first, second, and third pixel circuit portions PC1, PC2, and PC3. For example, the source area may be the source of the at least one transistor included in each of the first, second, and third pixel circuit portions. For example, the drain area may be the drain of the at least one transistor included in each of the first, second, and third pixel circuit portions. In an embodiment, the first, second, and third pixel circuit portions PC1, PC2, and PC3 may be spaced apart from each other in a plan view.

The insulating structure IL may be arranged on the transistor array substrate TS. For example, the insulating structure IL may cover the transistor array substrate TS. At least one contact hole penetrating the insulating structure IL in a thickness direction DR3 may be defined in the insulating structure IL.

In an embodiment, the insulating structure IL may include an inorganic material and/or an organic material. For example, the insulating structure IL may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zirconium oxide (ZrO₂), polyimide (PI), polyethersulfone (PES), polycarbonate (PC), BCB (Benzocyclobutene), HMDSO (hexamethyldisiloxane), TEOS (tetraethyl orthosilicate), FTEOS (fluorinate tetraethyl orthosilicate), and/or the like. These inorganic materials may be used alone or in any suitable combination with each other.

In an embodiment, the insulating structure IL may have a multilayered structure in which a plurality of layers are stacked. For example, the insulating structure IL may include a plurality of insulating layers, and a plurality of metal layers arranged between the insulating layers in a cross-section. For example, the plurality of metal layers may include gate electrodes, source electrodes, drain electrodes, and the like of the at least one transistor included in each of the first, second, and third pixel circuit portions PC1, PC2, and PC3. In an embodiment, the insulating structure IL may provide a flat or substantially flat upper surface.

Each of the first connection portion CP1, the second connection portion CP2, and the third connection portion CP3 may fill a corresponding contact hole of the insulating structure IL. For example, the first connection portion CP1 may fill a contact hole, and may electrically connect the first pixel circuit portion PC1 and the first pixel electrode PE1 to each other. Similarly, the second connection portion CP2 may fill a contact hole, and may electrically connect the second pixel circuit portion PC2 and the second pixel electrode PE2 to each other. The third connection portion CP3 may fill a contact hole, and may electrically connect the third pixel circuit portion PC3 and the third pixel electrode PE3 to each other.

The first lower electrode LE1 may be arranged on the insulating structure IL. For example, the first lower electrode LE1 may be arranged in the first light-emitting area LA1 on the insulating structure IL. In an embodiment, the first lower electrode LE1 may directly contact the first connection portion CP1. The first lower electrode LE1 may include a conductive material. For example, the conductive material may include titanium (Ti).

The second lower electrode LE2 may be arranged on the insulating structure IL. For example, the second lower electrode LE2 may be arranged in the second light-emitting area LA2 on the insulating structure IL. In an embodiment, the second lower electrode LE2 may directly contact the second connection portion CP2. The second lower electrode LE2 may include a conductive material. For example, the conductive material may include titanium (Ti). In an embodiment, the second lower electrode LE2 may be arranged in the same layer as that of the first lower electrode LE1. For example, the second lower electrode LE2 may include the same material as that of the first lower electrode LE1.

The third lower electrode LE3 may be arranged on the insulating structure IL. For example, the third lower electrode LE3 may be arranged in the third light-emitting area LA3 on the insulating structure IL. In an embodiment, the third lower electrode LE3 may directly contact the third connection portion CP3. The third lower electrode LE3 may include a conductive material. For example, the conductive material may include titanium (Ti). In an embodiment, the third lower electrode LE3 may be arranged in the same layer as that of the first lower electrode LE1. For example, the third lower electrode LE3 may include the same material as that of the first lower electrode LE1.

The first reflective electrode RE1 may be arranged on the first lower electrode LE1. For example, the first reflective electrode RE1 may be arranged in the first light-emitting area LA1 on the first lower electrode LE1. In an embodiment, the first reflective electrode RE1 may be a reflective electrode that reflects light. For example, the first reflective electrode RE1 may include silver (Ag), magnesium (Mg), aluminum (Al), platinum (Pt), palladium (Pd), gold (Au), nickel (Ni), neodymium (Nd), iridium (Ir), chromium (Cr), and/or the like. These materials may be used alone or in any suitable combination with each other. However, the materials included in the first reflective electrode RE1 according to embodiments of the present disclosure is not limited thereto.

In an embodiment, a thickness (e.g., a length in the third direction DR3) of the first reflective electrode RE1 may be greater than a thickness of the first lower electrode LE1. However, the thickness of the first reflective electrode RE1 according to embodiments of the present disclosure may be less than or substantially equal to the thickness of the first lower electrode LE1.

The second reflective electrode RE2 may be arranged on the second lower electrode LE2. For example, the second reflective electrode RE2 may be arranged in the second light-emitting area LA2 on the second lower electrode LE2. In an embodiment, the second reflective electrode RE2 may include the same material as that of the first reflective electrode RE1. For example, the second reflective electrode RE2 may be formed by the same process as that of the first reflective electrode RE1. The second reflective electrode RE2 may be arranged in the same layer as that of the first reflective electrode RE1.

In an embodiment, a thickness (e.g., a length in the third direction DR3) of the second reflective electrode RE2 may be greater than a thickness of the second lower electrode LE2. However, the thickness of the second reflective electrode RE2 according to embodiments of the present disclosure may be less than or substantially equal to the thickness of the second lower electrode LE2.

The third reflective electrode RE3 may be arranged on the third lower electrode LE3. For example, the third reflective electrode RE3 may be arranged in the third light-emitting area LA3 on the third lower electrode LE3. In an embodiment, the third reflective electrode RE3 may include the same material as that of the first reflective electrode RE1. For example, the third reflective electrode RE3 may be formed by the same process as that of the first reflective electrode RE1. The third reflective electrode RE3 may be arranged in the same layer as that of the first reflective electrode RE1.

In an embodiment, a thickness (e.g., a length in the third direction DR3) of the third reflective electrode RE3 may be greater than the thickness of the third lower electrode LE3. However, the thickness of the third reflective electrode RE3 according to embodiments of the present disclosure may be less than or substantially equal to the thickness of the third lower electrode LE3.

The first thickness compensation layer TL1 may be arranged on the first reflective electrode RE1. For example, the first thickness compensation layer TL1 may be arranged in the first light-emitting area LA1 on the first reflective electrode RE1. In an embodiment, the first thickness compensation layer TL1 may overlap with the first reflective electrode RE1 in a plan view.

In an embodiment, the first thickness compensation layer TL1 may include a material different from that of the first lower electrode LE1. The first thickness compensation layer TL1 may include an oxide. For example, the oxide may include silicon oxide (SiOₓ), silicon nitride (SiNₓ), silicon oxynitride (SiOxNy), aluminum oxide (Al₂O₃), titanium oxide (TiO₂), tantalum oxide (Ta₂O₅), hafnium oxide (HfO₂), zirconium oxide (ZrO₂), TEOS (tetraethyl orthosilicate), FTEOS (fluorinate tetraethyl orthosilicate), and/or the like. These materials may be used alone or in any suitable combination with each other. However, the materials included in the first thickness compensation layer TL1 according to embodiments of the present disclosure is not limited thereto.

In an embodiment, the second thickness compensation layer TL2 may be arranged on the first thickness compensation layer TL1. For example, the second thickness compensation layer TL2 may be arranged in the first light-emitting area LA1 on the first thickness compensation layer TL1. In an embodiment, the second thickness compensation layer TL2 may overlap with the first thickness compensation layer TL1 in a plan view.

In an embodiment, the second thickness compensation layer TL2 may include a material different from that of the first lower electrode LE1. The second thickness compensation layer TL2 may include the same material as that of the first thickness compensation layer TL1. In other embodiments, the first and second thickness compensation layers TL1 and TL2 may include different materials from each other.

In an embodiment, the second thickness compensation layer TL2 may include an oxide. For example, the oxide may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zirconium oxide (ZrO₂), TEOS (tetraethyl orthosilicate), FTEOS (fluorinate tetraethyl orthosilicate), and/or the like. These materials may be used alone or in any suitable combination with each other. However, the materials included in the second thickness compensation layer TL2 according to embodiments of the present disclosure is not limited thereto.

In an embodiment, a thickness (e.g., the length in the third direction DR3) of the second thickness compensation layer TL2 may be greater than a thickness of the first thickness compensation layer TL1. For example, the thickness of the first thickness compensation layer TL1 may be about 500 Å to about 800 Å. In addition, the thickness of the second thickness compensation layer TL2 may be about 600 Å to about 1000 Å. In more detail, the thickness of the first thickness compensation layer TL1 may be about 650 Å to 750 Å, and the thickness of the second thickness compensation layer TL2 may be about 750 Å to 900 Å. However, the first thickness compensation layer TL1 and the second thickness compensation layer TL2 according to embodiments of the present disclosure are not limited thereto, and the thicknesses of the first thickness compensation layer TL1 and the second thickness compensation layer TL2 may be equal to or substantially equal to each other, or the thickness of the second thickness compensation layer TL2 may be less than the thickness of the first thickness compensation layer TL1.

The third thickness compensation layer TL3 may be arranged on the second reflective electrode RE2. For example, the third thickness compensation layer TL3 may be arranged in the second light-emitting area LA2 on the second reflective electrode RE2. In an embodiment, the third thickness compensation layer TL3 may overlap with the second reflective electrode RE2 in a plan view.

In an embodiment, the third thickness compensation layer TL3 may include a material different from that of the second lower electrode LE2. The third thickness compensation layer TL3 may include the same material as that of the first thickness compensation layer TL1. For example, the third thickness compensation layer TL3 may be formed by the same process as that of the first thickness compensation layer TL1. The third thickness compensation layer TL3 may be arranged in the same layer as that of the first thickness compensation layer TL1.

In an embodiment, the third thickness compensation layer TL3 may include the same material as that of the second thickness compensation layer TL2. However, the second thickness compensation layer TL2 and the third thickness compensation layer TL3 according to embodiments of the present disclosure are not limited thereto, and may include different materials from each other.

In an embodiment, a thickness (e.g., the length in the third direction DR3) of the third thickness compensation layer TL3 may be equal to or substantially equal to the thickness of the first thickness compensation layer TL1. For example, the thickness of the third thickness compensation layer TL3 may be about 500 Å to about 800Å.

In an embodiment, the thickness of the third thickness compensation layer TL3 may be less than the thickness of the second thickness compensation layer TL2. However, the second thickness compensation layer TL2 and the third thickness compensation layer TL3 according to embodiments of the present disclosure are not limited thereto, and the thicknesses of each of the second thickness compensation layer TL2 and the third thickness compensation layer TL3 may be equal to or substantially equal to each other, or the thickness of the third thickness compensation layer TL3 may be greater than the thickness of the second thickness compensation layer TL2.

The dummy pattern DMP may be arranged on the third reflective electrode RE3. For example, the dummy pattern DMP may be arranged in the third light-emitting area LA3 on the third reflective electrode RE3. In more detail, the dummy pattern DMP may contact an edge portion of the third reflective electrode RE3.

In an embodiment, the dummy pattern DMP may overlap with the third reflective electrode RE3 in a plan view. For example, the dummy pattern DMP may overlap with the edge portion of the third reflective electrode RE3 in a plan view. In addition, the dummy pattern DMP may not overlap with a central portion of the third reflective electrode RE3 in a plan view. In more detail, the dummy pattern DMP may have an opening that extends over or exposes an upper surface of the third reflective electrode RE3. The opening may extend over the upper surface of the central portion of the third reflective electrode RE3.

In an embodiment, the dummy pattern DMP may include the same material as that of each of the first thickness compensation layer TL1 and the third thickness compensation layer TL3. The dummy pattern DMP may include the same material as that of the second thickness compensation layer TL2. However, the dummy pattern DMP is not limited thereto, and may include a material different from that of the second thickness compensation layer TL2.

The first transparent electrode TE1 may be arranged on the second thickness compensation layer TL2. For example, the first transparent electrode TE1 may be arranged in the first light-emitting area LA1 on the second thickness compensation layer TL2. In an embodiment, the first transparent electrode TE1 may directly contact side surfaces of the first lower electrode LE1, the first reflective electrode RE1, and the first thickness compensation layer TL1. In more detail, the first transparent electrode TE1 may extend from an upper portion of the second thickness compensation layer TL2 to the side surfaces of the first lower electrode LE1, the first reflective electrode RE1, and the first thickness compensation layer TL1.

In an embodiment, the first transparent electrode TE1 may cover an upper portion of the second thickness compensation layer TL2 and the side surfaces of the first lower electrode LE1, the first reflective electrode RE1, and the first thickness compensation layer TL1 with a uniform or substantially uniform thickness.

In an embodiment, the first transparent electrode TE1 may be a transparent electrode. For example, the first transparent electrode TE1 may include indium tin oxide (ITO), indium zinc oxide (IZO), zinc oxide (ZnO), indium oxide (In₂O₃), indium gallium oxide (IGO), aluminum zinc oxide (AZO), and/or the like. These materials may be used alone or in any suitable combination with each other.

In an embodiment, a thickness of the first transparent electrode TE1 may be less than a thickness of each of the first thickness compensation layer TL1 and the third thickness compensation layer TL3. The thickness of the first transparent electrode TE1 may be less than a thickness of the second thickness compensation layer TL2. However, the first transparent electrode TE1 according to embodiments of the present disclosure is not limited thereto.

The second transparent electrode TE2 may be arranged on the third thickness compensation layer TL3. For example, the second transparent electrode TE2 may be arranged in the second light-emitting area LA2 on the third thickness compensation layer TL3. In an embodiment, the second transparent electrode TE2 may directly contact side surfaces of the second lower electrode LE2 and the second reflective electrode RE2. In more detail, the second transparent electrode TE2 may extend from an upper portion of the third thickness compensation layer TL3 to the side surfaces of the second lower electrode LE2 and the second reflective electrode RE2.

In an embodiment, the second transparent electrode TE2 may cover the upper portion of the third thickness compensation layer TL3 and the side surfaces of the second lower electrode LE2 and the second reflective electrode RE2 with a uniform or substantially uniform thickness.

In an embodiment, the second transparent electrode TE2 may include the same material as that of the first transparent electrode TE1. For example, the second transparent electrode TE2 may be formed by a same process as that of the first transparent electrode TE1. A thickness (e.g., a length in the third direction DR3) of the second transparent electrode TE2 may be equal to or substantially equal to a thickness of the first transparent electrode TE1.

The third transparent electrode TE3 may be arranged on the third reflective electrode RE3. For example, the third transparent electrode TE3 may be arranged in the third light-emitting area LA3 on the third reflective electrode RE3.

In an embodiment, the third transparent electrode TE3 may contact an upper surface of the third reflective electrode RE3. For example, the third transparent electrode TE3 may fill the opening of the dummy pattern DMP, and may cover the upper surface of the third reflective electrode RE3. The third transparent electrode TE3 may contact side surfaces of the third lower electrode LE3, the third reflective electrode RE3, and the dummy pattern DMP. In more detail, the third transparent electrode TE3 may extend from an upper portion of the third reflective electrode RE3 to the side surfaces of the third lower electrode LE3, the third reflective electrode RE3, and the dummy pattern DMP.

In an embodiment, the third transparent electrode TE3 may cover the side surfaces of the third lower electrode LE3, the third reflective electrode RE3, and the dummy pattern DMP with a uniform or substantially uniform thickness from the upper portion of the third reflective electrode RE3.

In an embodiment, the third transparent electrode TE3 may include the same material as that of the first transparent electrode TE1. For example, the third transparent electrode TE3 may be formed by the same process as that of the first transparent electrode TE1. A thickness (e.g., a length in the third direction DR3) of the third transparent electrode TE3 may be equal to or substantially equal to the thickness of the first transparent electrode TE1.

In an embodiment, the center of the upper surface of the first transparent electrode TE1 may have a first height with reference to the transistor array substrate TS. In an embodiment, the center of the upper surface of the second transparent electrode TE2 may have a second height with reference to the transistor array substrate TS. In an embodiment, the center of the upper surface of the third transparent electrode TE3 may have a third height with reference to the transistor array substrate TS. In an embodiment, the second height may be less than the first height. In an embodiment, the third height may be less than the second height.

The first capping layer C1 may be arranged on the first transparent electrode TE1. In an embodiment, the first capping layer C1 may be arranged in the first light-emitting area LA1, and may partially surround (e.g., around a periphery of) the first transparent electrode TE1 in a cross-sectional view. For example, the first capping layer C1 may surround (e.g., around a periphery of) the upper surface and side surfaces of the first transparent electrode TE1. The second capping layer C2 may be arranged on the first capping layer C1. In an embodiment, the second capping layer C2 may be arranged in the first light-emitting area LA1, and may partially surround (e.g., around peripheries of) the first transparent electrode TE1 and the first capping layer C1 in a cross-sectional view.

The third capping layer C3 may be arranged on the second transparent electrode TE2. In an embodiment, the third capping layer C3 may be arranged in the second light-emitting area LA2, and may partially surround (e.g., around a periphery of) the second transparent electrode TE2 in a cross-sectional view. For example, the third capping layer C3 may surround (e.g., around a periphery of) the upper surface and side surfaces of the second transparent electrode TE2. The fourth capping layer C4 may be arranged on the third capping layer C3. In an embodiment, the fourth capping layer C4 may be arranged in the second light-emitting area LA2, and may partially surround (e.g., around peripheries of) the second transparent electrode TE2 and the third capping layer C3 in a cross-sectional view.

The fifth capping layer C5 may be arranged on the third transparent electrode TE3. In an embodiment, the fifth capping layer C5 may be arranged in the third light-emitting area LA3, and may partially surround (e.g., around a periphery of) the third transparent electrode TE3 in a cross-sectional view. For example, the fifth capping layer C5 may surround (e.g., around a periphery of) the upper surface and side surfaces of the third transparent electrode TE3. The sixth capping layer C6 may be arranged on the fifth capping layer C5. In an embodiment, the sixth capping layer C6 may be arranged in the third light-emitting area LA3, and may partially surround (e.g., around peripheries of) the third transparent electrode TE3 and the fifth capping layer C5 in a cross-sectional view.

In an embodiment, the first capping layer C1, the third capping layer C3, and the fifth capping layer C5 may include the same material as each other. For example, each of the first capping layer C1, the third capping layer C3, and the fifth capping layer C5 may include silicon oxide (SiOₓ). In an embodiment, the first capping layer C1, the third capping layer C3, and the fifth capping layer C5 may include the same material as that of the first thickness compensation layer TL1 and the third thickness compensation layer TL3. In an embodiment, the first capping layer C1, the third capping layer C3, and the fifth capping layer C5 may include the same material as that of the second thickness compensation layer TL2. However, the materials included in the first capping layer C1, the third capping layer C3, and the fifth capping layer C5 according to embodiments of the present disclosure are not limited thereto.

In an embodiment, the first capping layer C1, the third capping layer C3, and the fifth capping layer C5 may have a uniform or substantially uniform thickness. For example, the first capping layer C1 may have a uniform or substantially uniform thickness following a cross-sectional profile of the first transparent electrode TE1. For example, the third capping layer C3 may have a uniform or substantially uniform thickness following a cross-sectional profile of the second transparent electrode TE2. For example, the fifth capping layer C5 may have a uniform or substantially uniform thickness following a cross-sectional profile of the third transparent electrode TE3.

In an embodiment, the second capping layer C2, the fourth capping layer C4, and the sixth capping layer C6 may include the same material as each other. For example, each of the second capping layer C2, the fourth capping layer C4, and the sixth capping layer C6 may include silicon nitride (SiNₓ). However, the materials included in the second capping layer C2, the fourth capping layer C4, and the sixth capping layer C6 according to embodiments of the present disclosure are not limited thereto.

In an embodiment, the second capping layer C2, the fourth capping layer C4, and the sixth capping layer C6 may have a uniform or substantially uniform thickness. For example, the second capping layer C2 may have a uniform or substantially uniform thickness following a cross-sectional profile of the first capping layer C1. For example, the fourth capping layer C4 may have a uniform or substantially uniform thickness following a cross-sectional profile of the third capping layer C3. For example, the sixth capping layer C6 may have a uniform or substantially uniform thickness following a cross-sectional profile of the fifth capping layer C5.

The planarization layer PL may be arranged on the insulating structure IL. In an embodiment, the planarization layer PL may be arranged in the display area DA. In more detail, the planarization layer PL may be arranged across a plurality of non-light-emitting areas, and the planarization layer PL may be partially arranged in the second light-emitting area LA2 and the third light-emitting area LA3. However, the planarization layer PL according to the embodiments of the present disclosure is not limited thereto, and the planarization layer PL may also be arranged in the first light-emitting area LA1. In an embodiment, the planarization layer PL may include an organic insulating material.

In an embodiment, a plurality of first openings OP1 overlapping with the first, second, and third pixel electrodes PE1, PE2, and PE3, respectively, may be defined in the planarization layer PL. The plurality of first openings OP1 may include a first-first opening OP1-1 located in the first light-emitting area LA1, a first-second opening OP1-2 located in the second light-emitting area LA2, and a first-third opening OP1-3 located in the third light-emitting area LA3.

In an embodiment, the planarization layer PL may have a flat or substantially flat upper surface across the display area DA. In an embodiment, the planarization layer PL may have an equal or substantially equal height (e.g., the same or substantially the same height) based on the transistor array substrate TS in the display area DA. For example, the upper surface of the planarization layer PL may have an equal or substantially equal height (e.g., the same or substantially the same height) based on the transistor array substrate TS in each of the first light-emitting area LA1, the second light-emitting area LA2, the third light-emitting area LA3, and the non-light-emitting area NLA.

In more detail, the upper surface of the planarization layer PL arranged in the non-light-emitting area NLA located in the first direction DR1 from the first light-emitting area LA1 may have an equal or substantially equal height based on the transistor array substrate TS as that of the upper surface of the planarization layer PL arranged in the non-light-emitting area NLA located in the first direction DR1 from the second light-emitting area LA2.

In addition, the upper surface of the planarization layer PL in the non-light-emitting area NLA located in the first direction DR1 from the second light-emitting area LA2 may have an equal or substantially equal height based on the transistor array substrate TS as that of the upper surface of the planarization layer PL in the non-light-emitting area NLA located in the first direction DR1 from the third light-emitting area LA3.

The upper surface of the planarization layer PL in the non-light-emitting area NLA located in the first direction DR1 from the third light-emitting area LA3 may have an equal or substantially equal height based on the transistor array substrate TS as that of the upper surface of the planarization layer PL in the non-light-emitting area NLA located in the first direction DR1 from the first light-emitting area LA1.

In other words, a maximum thickness (e.g., a length in the third direction DR3 from a lower surface of the planarization layer PL contacting the insulating structure IL to the upper surface located at a maximum height of the planarization layer PL) of the planarization layer PL may be equal or substantially equal (e.g., may be the same or substantially the same) in each of the non-light-emitting areas adjacent to the first light-emitting area LA1, the second light-emitting area LA2, and the third light-emitting area LA3.

For example, the maximum thickness of the planarization layer PL arranged between the first light-emitting area LA1 and the second light-emitting area LA2 may be equal to or substantially equal to the maximum thickness of the planarization layer PL arranged between the second light-emitting area LA2 and the third light-emitting area LA3. For example, the maximum thickness of the planarization layer PL arranged between the second light-emitting area LA2 and the third light-emitting area LA3 may be equal to or substantially equal to the maximum thickness of the planarization layer PL arranged between the third light-emitting area LA3 and the first light-emitting area LA1. For example, the maximum thickness of the planarization layer PL arranged between the third light-emitting area LA3 and the first light-emitting area LA1 may be equal to or substantially equal to the maximum thickness of the planarization layer PL arranged between the first light-emitting area LA1 and the second light-emitting area LA2.

As used herein, the expression “the planarization layer PL has an equal or substantially equal” height across the first light-emitting area LA1, the second light-emitting area LA2, the third light-emitting area LA3, and the non-light-emitting area NLA″ may include not only physically equal heights, but may also include cases in which there may be differences within a range of a process error, despite having an equal or substantially equal design. For example, the process error range may be about ±150Å.

In an embodiment, a plurality of second openings OP2 overlapping with the first, second, and third pixel electrodes PE1, PE2, and PE3, respectively, may be defined in the first, second, third, fourth, fifth, and sixth capping layers C1, C2, C3, C4, C5, and C6. The plurality of second openings OP2 may include a second-first opening OP2-1 located in the first light-emitting area LA1, a second-second opening OP2-2 located in the second light-emitting area LA2, and a second-third opening OP2-3 located in the third light-emitting area LA3.

In an embodiment, the first capping layer C1 and the second capping layer C2 may have the second-first opening OP2-1 that exposes an upper surface of the first transparent electrode TE1. For example, the second-first opening OP2-1 may penetrate the first and second capping layers C1 and C2 in a thickness direction (e.g., the third direction DR3). In more detail, the first and second capping layers C1 and C2 may contact an edge portion of the first transparent electrode TE1. In addition, the first and second capping layers C1 and C2 may not overlap with the central portion of the first transparent electrode TE1 in a plan view.

In an embodiment, the planarization layer PL may contact a side surface of the second capping layer C2. In more detail, the upper surface of the planarization layer PL may be connected to the upper surface of the second capping layer C2, thereby providing a flat or substantially flat upper surface. In other words, the upper surface of the planarization layer PL may have an equal or substantially equal height to that of the upper surface of the second capping layer C2 based on the transistor array substrate TS.

In an embodiment, the second-second opening OP2-2 that exposes the upper surface of the second transparent electrode TE2 may be defined in the third capping layer C3, the fourth capping layer C4, and the planarization layer PL. For example, the second-second opening OP2-2 may penetrate the third capping layer C3, the fourth capping layer C4, and the planarization layer PL in the thickness direction (e.g., the third direction DR3). In an embodiment, the planarization layer PL may not overlap with a portion of the second transparent electrode TE2 in a plan view where the second-second opening OP2-2 extends.

In an embodiment, the planarization layer PL may contact the upper surface and side surface of the fourth capping layer C4. In more detail, the upper surface of the planarization layer PL may have a height greater than that of the upper surface of the fourth capping layer C4 based on the transistor array substrate TS. In other words, the upper surface of the second capping layer C2 may have a height greater than that of the upper surface of the fourth capping layer C4 based on the transistor array substrate TS.

In an embodiment, the second-third opening OP2-3 that exposes the upper surface of the third transparent electrode TE3 may be defined in the fifth capping layer C5, the sixth capping layer C6, and the planarization layer PL. For example, the second-third opening OP2-3 may penetrate the fifth capping layer C5, the sixth capping layer C6, and the planarization layer PL in the thickness direction (e.g., the third direction DR3).

In an embodiment, the planarization layer PL may contact the upper surface and side surface of the sixth capping layer C6. In more detail, the upper surface of the planarization layer PL may have a height greater than that of the upper surface of the sixth capping layer C6 based on the transistor array substrate TS. In other words, the upper surface of the second capping layer C2 may have a height greater than that of the upper surface of the sixth capping layer C6 based on the transistor array substrate TS.

In an embodiment, the second-first opening OP2-1 may overlap with the first pixel electrode PE1. In an embodiment, the second-first opening OP2-1 may overlap with the first thickness compensation layer TL1 in a plan view. In an embodiment, the second-first opening OP2-1 may overlap with the second thickness compensation layer TL2 in a plan view. In an embodiment, the second-first opening OP2-1 may be located within the first-first opening OP1-1 in a plan view.

In an embodiment, the second-second opening OP2-2 may overlap with the second pixel electrode PE2. In an embodiment, the second-second opening OP2-2 may overlap with the third thickness compensation layer TL3 in a plan view. In an embodiment, the second-second opening OP2-2 may be connected to the first-second opening OP1-2. For example, side surfaces of the third and fourth capping layers C3 and C4 defining the first-second opening OP1-2 and the side surface of the planarization layer PL defining the second-second opening OP2-2 may be connected to each other.

In an embodiment, the second-third opening OP2-3 may overlap with the third pixel electrode PE3. In an embodiment, the second-third opening OP2-3 may be spaced apart from the dummy pattern DMP in a plan view. For example, the second-third opening OP2-3 may not overlap with the dummy pattern DMP in a plan view. In an embodiment, the second-third opening OP2-3 may be connected to the first-third opening OP1-3. For example, side surfaces of the fifth and sixth capping layers C5 and C6 defining the first-third opening OP1-3 and the side surface of the planarization layer PL defining the second-third opening OP2-3 may be connected to each other.

A first separation structure SP1, a second separation structure SP2, and a third separation structure SP3 may be arranged on the planarization layer PL. In an embodiment, the first separation structure SP1, the second separation structure SP2, and the third separation structure SP3 may be arranged in the non-light-emitting area NLA. In more detail, the first separation structure SP1 may be arranged in the non-light-emitting area NLA located in the first direction DR1 from the first light-emitting area LA1. The second separation structure SP2 may be arranged in the non-light-emitting area NLA located in the first direction DR1 from the second light-emitting area LA2. The third separation structure SP3 may be arranged in the non-light-emitting area NLA located in the first direction DR1 from the third light-emitting area LA3.

In an embodiment, a portion of the first separation structure SP1 may be arranged in the first light-emitting area LA1. In an embodiment, a portion of the second separation structure SP2 may be arranged in the second light-emitting area LA2. In an embodiment, a portion of the third separation structure SP3 may be arranged in the third light-emitting area LA3.

The first separation structure SP1 may include a first layer SP1a, a second layer SP1b, and a third layer SP1c. The second separation structure SP2 may include a first layer SP2a, a second layer SP2b, and a third layer SP2c. The third separation structure SP3 may include a first layer SP3a, a second layer SP3b, and a third layer SP3c.

The second layer SP1b of the first separation structure SP1 may be arranged on the first layer SP1a of the first separation structure SP1. The third layer SP1c of the first separation structure SP1 may be arranged on the second layer SP1b of the first separation structure SP1.

In an embodiment, the first layer SP1a of the first separation structure SP1 may include silicon oxide (SiOₓ). In an embodiment, the second layer SP1b of the first separation structure SP1 may include silicon nitride (SiNₓ). In an embodiment, the third layer SP1c of the first separation structure SP1 may include the same material as that of the first layer SP1a of the first separation structure SP1. In an embodiment, the third layer SP1c of the first separation structure SP1 may include a material different from that of the second layer SP1b of the first separation structure SP1. However, the materials included in each of the first layer SP1a, the second layer SP1b, and the third layer SP1c of the first separation structure SP1 according to the embodiments of the present disclosure are not limited thereto.

In an embodiment, in a plan view, a size of the first layer SP1a of the first separation structure SP1 may be greater than a size of the second layer SP1b of the first separation structure SP1. In an embodiment, in a plan view, the size of the second layer SP1b of the first separation structure SP1 may be less than the size of the third layer SP1c of the first separation structure SP1. In more detail, the length of the first layer SP1a in the first direction DR1 may be greater than the length of the second layer SP1b in the first direction DR1. The length of the second layer SP1b in the first direction DR1 may be less than the length of the third layer SP1c in the first direction DR1. However, the sizes of the first layer SP1a, the second layer SP1b, and the third layer SP1c of the first separation structure SP1 in a plan view according to the embodiments of the present disclosure are not limited thereto.

The first separation structure SP1 is described in more detail above with reference to FIG. 3, and each of the second separation structure SP2 and the third separation structure SP3 may have the same or substantially the same layer structure, material arrangement, and size relationship as those of the first separation structure SP1.

Dummy layers DML may be arranged on the first separation structure SP1, the second separation structure SP2, and the third separation structure SP3. In an embodiment, the dummy layers DML may include the same material as those of the first light-emitting layer EM1, the second light-emitting layer EM2, and the third light-emitting layer EM3. In an embodiment, the dummy layers DML may be formed through the same process as those of the first light-emitting layer EM1, the second light-emitting layer EM2, and the third light-emitting layer EM3. For example, when a material for forming the first light-emitting layer EM1, the second light-emitting layer EM2, and the third light-emitting layer EM3 is applied across the first light-emitting area LA1, the second light-emitting area LA2, the third light-emitting area LA3, and the non-light-emitting area NLA, the material may be applied on the first separation structure SP1, the second separation structure SP2, and the third separation structure SP3 to form the dummy layers DML.

The first light-emitting layer EM1 may be arranged on the first pixel electrode PE1. For example, the first light-emitting layer EM1 may be arranged in the first light-emitting area LA1 on the first pixel electrode PE1. In an embodiment, the first light-emitting layer EM1 may emit light of a first color. In an embodiment, the first light-emitting layer EM1 may fill the second-first opening OP2-1. In an embodiment, the first light-emitting layer EM1 may extend along the first and second capping layers C1 and C2, and may contact the upper surface of the first layer SP1a of the first separation structure SP1 and the upper surface of the first layer SP3a of the third separation structure SP3.

The second light-emitting layer EM2 may be arranged on the second pixel electrode PE2. For example, the second light-emitting layer EM2 may be arranged in the second light-emitting area LA2 on the second pixel electrode PE2. In an embodiment, the second light-emitting layer EM2 may emit light of a second color. In an embodiment, the second light-emitting layer EM2 may fill the second-second opening OP2-2. In an embodiment, the second light-emitting layer EM2 may extend along the third and fourth capping layers C3 and C4 and the planarization layer PL, and may contact the upper surface of the first layer SP1a of the first separation structure SP1 and the upper surface of the first layer SP2a of the second separation structure SP2.

The third light-emitting layer EM3 may be arranged on the third pixel electrode PE3. For example, the third light-emitting layer EM3 may be arranged in the third light-emitting area LA3 on the third pixel electrode PE3. In an embodiment, the third light-emitting layer EM3 may emit light of a third color. In an embodiment, the third light-emitting layer EM3 may fill the second-third opening OP2-3. In an embodiment, the third light-emitting layer EM3 may extend along the fifth and sixth capping layers C5 and C6 and the planarization layer PL, and may contact the upper surface of the first layer SP2a of the second separation structure SP2 and the upper surface of the first layer SP3a of the third separation structure SP3.

Each of the first light-emitting layer EM1, the second light-emitting layer EM2, and the third light-emitting layer EM3 may include an organic light-emitting material. The organic light-emitting material may include a low molecular organic compound or a high molecular organic compound. However, the present disclosure is not limited thereto, and each of the first light-emitting layer EM1, the second light-emitting layer EM2, and the third light-emitting layer EM3 may include a suitable material, such as quantum dots.

The common electrode CE may be arranged on the planarization layer PL. In an embodiment, the common electrode CE may be arranged across the first light-emitting area LA1, the second light-emitting area LA2, the third light-emitting area LA3, and the non-light-emitting area NLA. In an embodiment, the common electrode CE may be arranged on the first separation structure SP1, the second separation structure SP2, the third separation structure SP3, the first light-emitting layer EM1, the second light-emitting layer EM2, and the third light-emitting layer EM3.

In the non-light-emitting area NLA, the common electrode CE may have an upper surface having the same or substantially the same height (e.g., a constant or substantially constant height) based on the transistor array substrate TS. In an embodiment, the common electrode CE may include a conductive material.

In an embodiment, light of the first color emitted from the first light-emitting layer EM1 arranged in the first light-emitting area LA1 may resonate between the first pixel electrode PE1 and the common electrode CE. In more detail, the light of the first color emitted from the first light-emitting layer EM1 arranged in the first light-emitting area LA1 may resonate between the first reflective electrode RE1 and the common electrode CE.

In an embodiment, light of the second color emitted from the second light-emitting layer EM2 arranged in the second light-emitting area LA2 may resonate between the second pixel electrode PE2 and the common electrode CE. In more detail, the light of the second color emitted from the second light-emitting layer EM2 arranged in the second light-emitting area LA2 may resonate between the second reflective electrode RE2 and the common electrode CE.

In an embodiment, light of the third color emitted from the third light-emitting layer EM3 arranged in the third light-emitting area LA3 may resonate between the third pixel electrode PE3 and the common electrode CE. In more detail, the light of the third color emitted from the third light-emitting layer EM3 arranged in the third light-emitting area LA3 may resonate between the third reflective electrode RE3 and the common electrode CE.

A first resonance distance, which may be defined as a shortest distance between a portion of the common electrode CE located in the first light-emitting area LA1 and the first reflective electrode RE1, may be defined. For example, the first resonance distance may be a distance from the upper surface of the first reflective electrode RE1 to the lower surface of the first common electrode CE facing the upper surface of the first reflective electrode RE1 in the first light-emitting area LA1.

A second resonance distance, which may be defined as a shortest distance between a portion of the common electrode CE located in the second light-emitting area LA2 and the second reflective electrode RE2, may be defined. For example, the second resonance distance may be a distance from the upper surface of the second reflective electrode RE2 to the lower surface of the second common electrode CE facing the upper surface of the second reflective electrode RE2 in the second light-emitting area LA2.

A third resonance distance, which may be defined as a shortest distance between a portion of the common electrode CE located in the third light-emitting area LA3 and the third reflective electrode RE3, may be defined. For example, the third resonance distance may be a distance from the upper surface of the third reflective electrode RE3 to the lower surface of the third common electrode CE facing the upper surface of the third reflective electrode RE3 in the third light-emitting area LA3.

The first resonance distance, the second resonance distance, and the third resonance distance may satisfy Equation 1.

RL=(λ/2)×N Equation 1

In Equation 1, RL is a resonance distance, λ is a median value of a wavelength band of light emitted from a light-emitting layer, and N is a natural number.

Referring to Equation 1, when the light of the first color is a red light, its wavelength band may be about 610 nm to about 700 nm. Accordingly, λ may be about 655 nm, which is the median value of the wavelength band of the first color light, and the resonance distance RL may be an integer multiple of about 377.5 nm, which is half of the median value of the wavelength band of the first color light. The value of the resonance distance RL calculated for the light of the first color may be the first resonance distance.

Therefore, when a portion of the first color light emitted from the first light-emitting layer EM1 arranged in the first light-emitting area LA1 is incident toward the first reflective electrode RE1 and reflected from the first reflective electrode RE1, and another portion of the first color light proceeds toward the common electrode CE, the portion of the first color light and the other portion of the first color may interfere constructively with each other, thereby improving the light-emitting efficiency of the first color light.

Referring to Equation 1, when the light of the second color is a green light, its wavelength band is about 500 nm to about 570 nm, and thus, λ may be about 535 nm, which is the median value of the wavelength band of the second color light, and the resonance distance RL may be an integer multiple of about 267.5 nm, which is half of the median value of the wavelength band of the second color light. The value of the resonance distance RL calculated for the light of the second color may be the second resonance distance.

Therefore, when a portion of the second color light emitted from the second light-emitting layer EM2 arranged in the second light-emitting area LA2 is incident toward the second reflective electrode RE2 and reflected from the second reflective electrode RE2, and another portion of the second color light proceeds toward the common electrode CE, the portion of the second color light and the other portion of the second color light may interfere constructively with each other, thereby improving the light-emitting efficiency of the second color light.

Referring to Equation 1, when the light of the third color is blue light, its wavelength band is about 450 nm to about 500 nm, and thus, λ may be about 475 nm, which is the median value of the wavelength band of the third color light, and the resonance distance RL may be an integer multiple of about 237.5 nm, which is half of the median value of the wavelength band of the third color light. The value of the resonance distance RL calculated for the light of the third color may be the third resonance distance.

Therefore, when a portion of the third color light emitted from the third light-emitting layer EM3 arranged in the third light-emitting area LA3 is incident toward the third reflective electrode RE3 and reflected from the third reflective electrode RE3, and another portion of the third color light proceeds toward the common electrode CE, the portion of the third color light and the other portion of the third color light may interfere constructively with each other, thereby improving the light-emitting efficiency of the third color light.

In an embodiment, the first resonance distance may be greater than the second resonance distance. In an embodiment, the first resonance distance may be greater than the third resonance distance. In an embodiment, the second resonance distance may be greater than the third resonance distance.

The thin film encapsulation layer TFE may be arranged on the common electrode CE. For example, the thin film encapsulation layer TFE may be arranged across the first light-emitting area LA1, the second light-emitting area LA2, the third light-emitting area LA3, and the non-light-emitting area NLA.

The thin film encapsulation layer TFE may include at least one inorganic encapsulation layer and at least one organic encapsulation layer. In an embodiment, the inorganic encapsulation layer and the organic encapsulation layer may be alternately arranged. For example, the organic encapsulation layer may include a polymer cured material, such as polyacrylate, an epoxy resin, or a silicone resin. These materials may be used alone or in any suitable combination with each other.

For example, the inorganic encapsulation layer may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO2), zinc oxide (ZrO₂), and/or the like. These materials may be used alone or in any suitable combination with each other. The thin film encapsulation layer TFE may prevent or substantially prevent impurities from entering the first light-emitting element EE1, the second light-emitting element EE2, and the third light-emitting element EE3.

The color filter layer CFL may be arranged on the thin film encapsulation layer TFE. For example, the color filter layer CFL may be arranged across the first light-emitting area LA1, the second light-emitting area LA2, the third light-emitting area LA3, and the non-light-emitting area NLA. The color filter layer CFL may include a first color filter CF1, a second color filter CF2, a third color filter CF3, and a black matrix BM.

The first color filter CF1 may be arranged to overlap with the first light-emitting area LA1. The first color filter CF1 may transmit the first light, and may absorb or block the second light and the third light. For example, the first color filter CF1 may transmit light in the red wavelength band, and may absorb or block light in other wavelength bands, such as green or blue, but the present disclosure is not limited thereto.

The second color filter CF2 may be arranged to overlap with the second light-emitting area LA2. The second color filter CF2 may transmit the second light, and may absorb or block the first light and the third light. For example, the second color filter CF2 may transmit light in the green wavelength band, and may absorb or block light in other wavelength bands, such as blue or red, but the present disclosure is not limited thereto.

The third color filter CF3 may be arranged to overlap with the third light-emitting area LA3. The third color filter CF3 may transmit the third light, and may absorb or block the first light and the second light. For example, the third color filter CF3 may transmit light in the blue wavelength band, and may absorb or block light in other wavelength bands, such as green or red, but the present disclosure is not limited thereto.

In an embodiment, the black matrix BM may be arranged in the non-light-emitting area NLA to block light. In an embodiment, the black matrix BM may be arranged in a plan view between the first color filter CF1, the second color filter CF2, and the third color filter CF3.

The encapsulation substrate ES may be arranged on the color filter layer CFL. For example, the encapsulation substrate ES may be arranged across the first light-emitting area LA1, the second light-emitting area LA2, the third light-emitting area LA3, and the non-light-emitting area NLA.

In an embodiment, the encapsulation substrate ES may include a transparent material. For example, the encapsulation substrate ES may include a transparent resin substrate. For example, the transparent resin substrate may include an insulating material, such as glass or a plastic. These materials may be used alone or in any suitable combination with each other. However, the encapsulation substrate ES according to the embodiments of the present disclosure is not limited thereto, and the encapsulation substrate ES may also include an organic polymer material, such as polycarbonate (PC), polyethylene (PE), or polypropylene (PP).

As described above, in the display device DD according to some embodiments of the present disclosure, the first pixel electrode PE1 in the first light-emitting area LA1 may include two thickness compensation layers (e.g., the first and second thickness compensation layers TL1 and TL2), and the second pixel electrode PE2 in the second light-emitting area LA2 may include one thickness compensation layer (e.g., the third thickness compensation layer TL3). Accordingly, a resonance distance at which a constructive interference generated for each of the first color light, the second color light, and the third color light emitted from the light-emitting layers (e.g., the first, second, and third light-emitting layers EM1, EM2, and EM3) may be secured (e.g., may be easily secured). Therefore, because the implementation efficiency of the first color light, the second color light, and the third color light of the display device DD may be improved, a display quality of the display device DD may be improved.

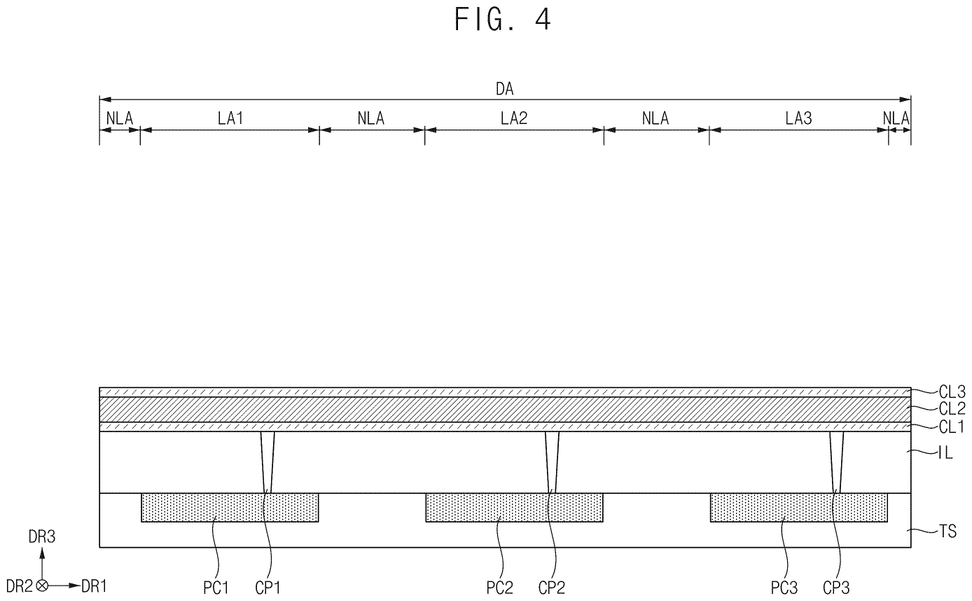

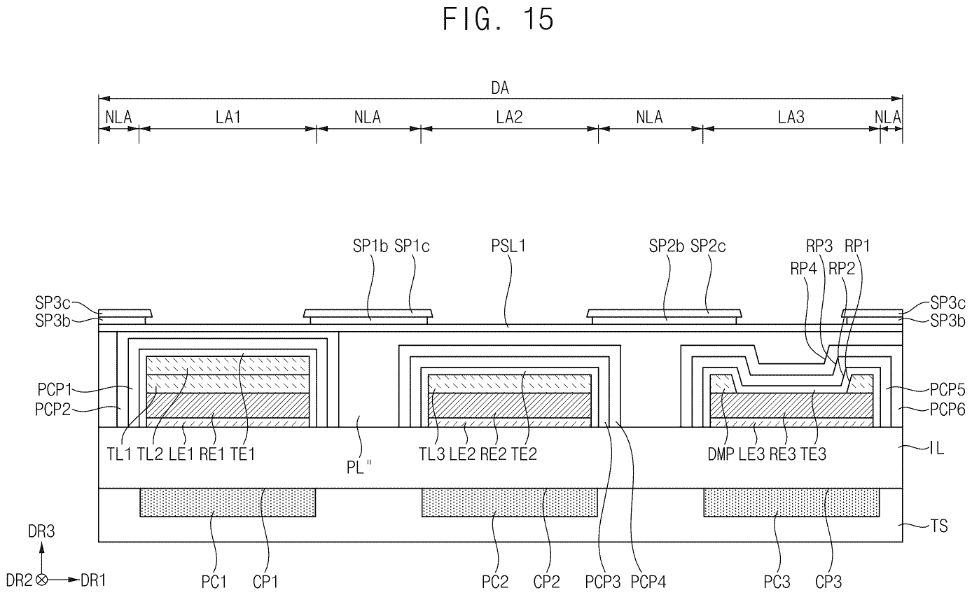

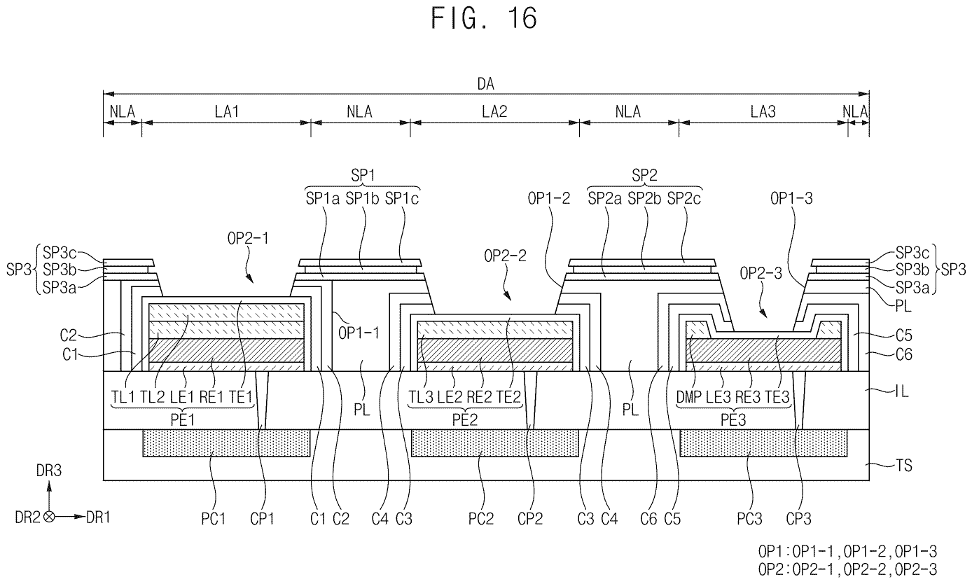

FIGS. 4 through 17 are views illustrating a method of manufacturing the display device of FIG. 1.

Referring to FIG. 4, an insulating structure IL may be formed on the transistor array substrate TS including the first pixel circuit portion PC1, the second pixel circuit portion PC2, and the third pixel circuit portion PC3. A first conductive layer CL1 may be formed on the insulating structure IL. A second conductive layer CL2 may be formed on the first conductive layer CL1. A third conductive layer CL3 may be formed on the second conductive layer CL2. The second conductive layer CL2 may be referred to as a reflective electrode layer.

In an embodiment, the first conductive layer CL1 may contact each of the first connection portion CP1, the second connection portion CP2, and the third connection portion CP3. In an embodiment, the first conductive layer CL1, the second conductive layer CL2, and the third conductive layer CL3 may be sequentially formed on the insulating structure IL across the first light-emitting area LA1, the second light-emitting area LA2, the third light-emitting area LA3, and the non-light-emitting area NLA.

In an embodiment, the first conductive layer CL1 may include a conductive material. For example, the conductive material may include titanium Ti. In an embodiment, the second conductive layer CL2 may include silver (Ag), magnesium (Mg), aluminum (Al), platinum (Pt), palladium (Pd), gold (Au), nickel (Ni), neodymium (Nd), iridium (Ir), chromium (Cr), and/or the like. These materials may be used alone or in any suitable combination with each other. However, the present disclosure is not limited thereto. In an embodiment, the third conductive layer CL3 may include the same material as that of the first conductive layer CL1.

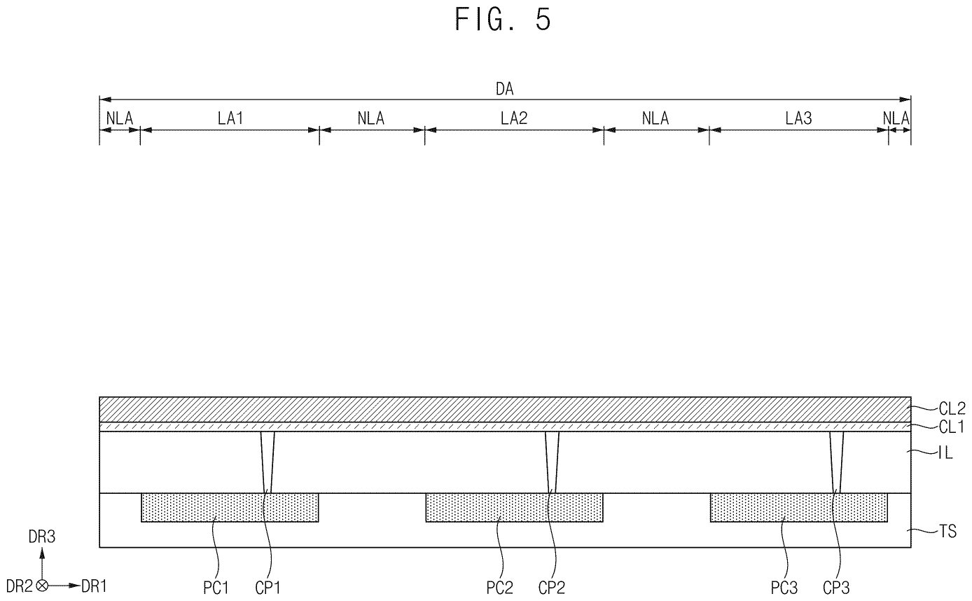

Referring to FIGS. 4 and 5, the third conductive layer CL3 may be removed. For example, the third conductive layer CL3 formed on the second conductive layer CL2 may be entirely removed. Accordingly, the upper surface of the second conductive layer CL2 may be entirely exposed.

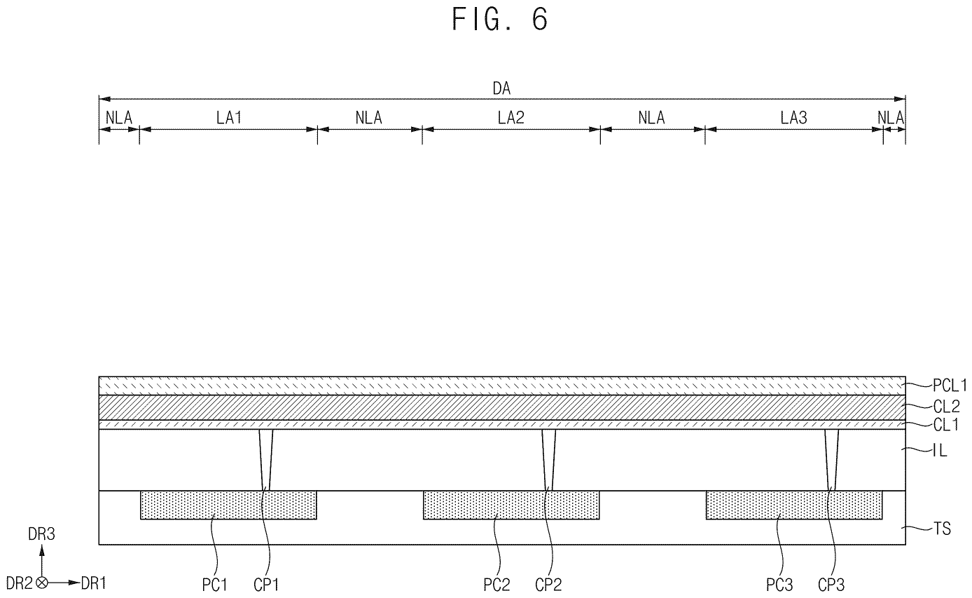

Referring to FIG. 6, a first preliminary thickness compensation layer PCL1 may be formed on the second conductive layer CL2. For example, the first preliminary thickness compensation layer PCL1 may be formed on the second conductive layer CL2 across the first light-emitting area LA1, the second light-emitting area LA2, the third light-emitting area LA3, and the non-light-emitting area NLA.

In an embodiment, the first preliminary thickness compensation layer PCL1 may include an oxide. For example, the oxide may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZrO₂), tetraethyl orthosilicate (TEOS), fluorinated tetraethyl orthosilicate (FTEOS), and/or the like. These materials may be used alone or in any suitable combination with each other.

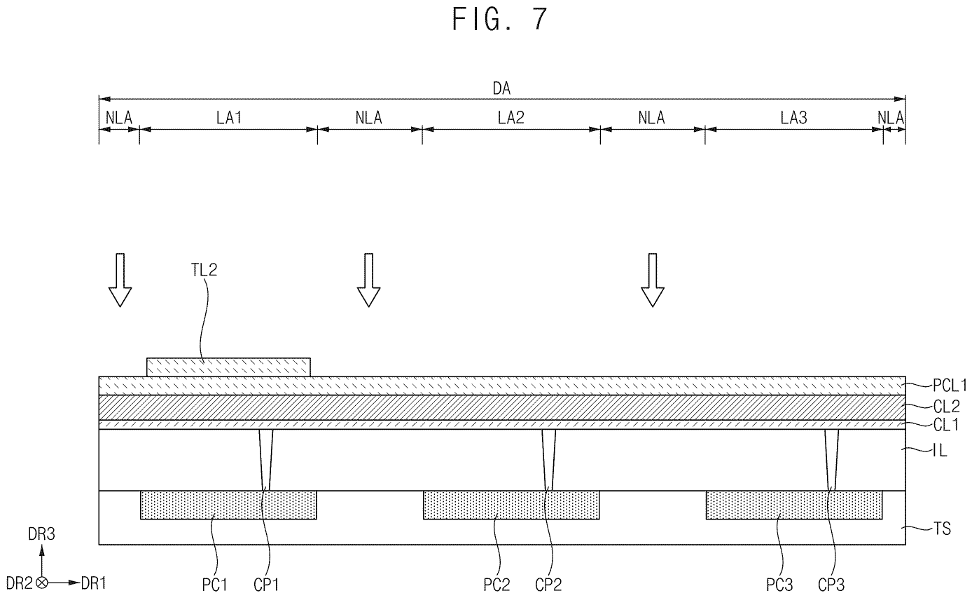

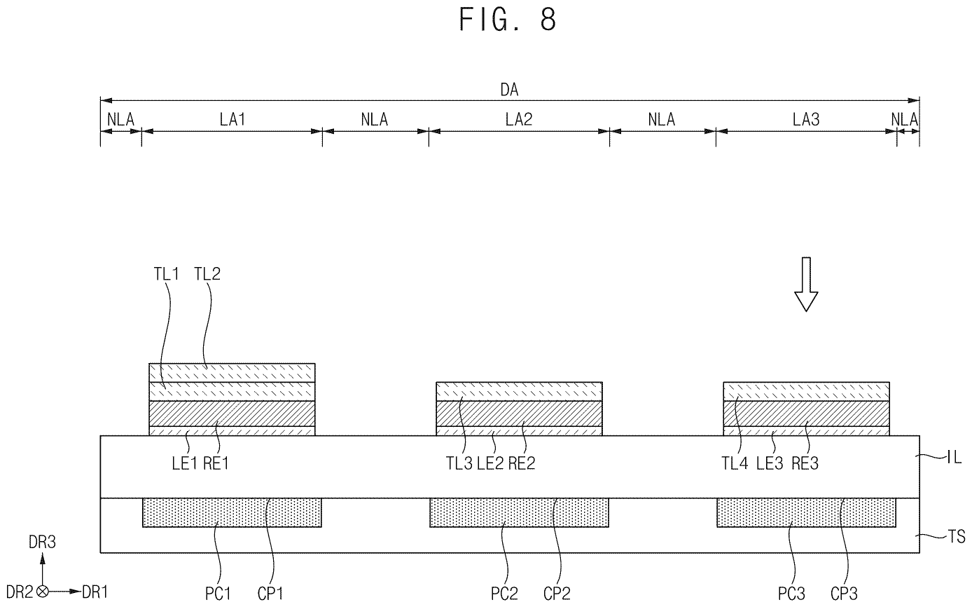

Referring to FIGS. 7 and 8, in an embodiment, a second thickness compensation layer TL2 may be formed on the first preliminary thickness compensation layer PCL1. For example, the second thickness compensation layer TL2 may be formed in the first light-emitting area LA1 on the first preliminary thickness compensation layer PCL1. In other words, the second thickness compensation layer TL2 may not be formed in the second light-emitting area LA2, the third light-emitting area LA3, and the non-light-emitting area NLA.

In an embodiment, the second thickness compensation layer TL2 may be formed by patterning a second preliminary thickness compensation layer that entirely covers the first preliminary thickness compensation layer PCL1. In more detail, after forming the second preliminary thickness compensation layer, a portion of the second preliminary thickness compensation layer located in the first light-emitting area LA1 may remain, while other portions may be removed or partially removed, thereby forming the second thickness compensation layer TL2. However, a formation process of the second thickness compensation layer TL2 according to the embodiments of the present disclosure is not limited thereto.

The first preliminary thickness compensation layer PCL1 and the second preliminary thickness compensation layer may be referred to as a preliminary thickness compensation layer.

In an embodiment, the second thickness compensation layer TL2 may include an oxide. For example, the oxide may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZrO₂), tetraethyl orthosilicate (TEOS), fluorinated tetraethyl orthosilicate (FTEOS), and/or the like. These materials may be used alone or in any suitable combination with each other.

In an embodiment, the second thickness compensation layer TL2 may include the same material as that of the first preliminary thickness compensation layer PCL1. In another embodiment, the second thickness compensation layer TL2 may include a material different from that of the first preliminary thickness compensation layer PCL1.

In an embodiment, a thickness (e.g., a length in the third direction DR3) of the second thickness compensation layer TL2 may be greater than a thickness of the first preliminary thickness compensation layer PCL1. However, the second thickness compensation layer TL2 is not limited thereto, and its thickness may be smaller than or equal to that of the first preliminary thickness compensation layer PCL1.

A portion of the first preliminary thickness compensation layer PCL1 may be removed, and the first thickness compensation layer TL1, the third thickness compensation layer TL3, and a fourth thickness compensation layer TL4 may be formed. In more detail, while a portion of the first preliminary thickness compensation layer PCL1 is removed, a portion of the first preliminary thickness compensation layer PCL1 located in the first light-emitting area LA1 may remain, thereby forming the first thickness compensation layer TL1. In addition, a portion of the first preliminary thickness compensation layer PCL1 located in the second light-emitting area LA2 may remain, thereby forming the third thickness compensation layer TL3. Furthermore, a portion of the first preliminary thickness compensation layer PCL1 located in the third light-emitting area LA3 may remain, thereby forming the fourth thickness compensation layer TL4.

The fourth thickness compensation layer TL4 may be referred to as the third thickness compensation layer.

Also, a portion of the second conductive layer CL2 may be removed, thereby forming the first reflective electrode RE1, the second reflective electrode RE2, and the third reflective electrode RE3. In more detail, while a portion of the second conductive layer CL2 is removed, a portion of the second conductive layer CL2 located in the first light-emitting area LA1 may remain, thereby forming the first reflective electrode RE1. In addition, a portion of the second conductive layer CL2 located in the second light-emitting area LA2 may remain, thereby forming the second reflective electrode RE2. Furthermore, a portion of the second conductive layer CL2 located in the third light-emitting area LA3 may remain, thereby forming the third reflective electrode RE3.

In addition, a portion of the first conductive layer CL1 may be removed, thereby forming the first lower electrode LE1, the second lower electrode LE2, and the third lower electrode LE3. In more detail, while a portion of the first conductive layer CL1 is removed, a portion of the first conductive layer CL1 located in the first light-emitting area LA1 may remain, thereby forming the first lower electrode LE1. In addition, a portion of the first conductive layer CL1 located in the second light-emitting area LA2 may remain, thereby forming the second lower electrode LE2. Furthermore, a portion of the first conductive layer CL1 located in the third light-emitting area LA3 may remain, thereby forming the third lower electrode LE3.

In an embodiment, a portion of each of the first preliminary thickness compensation layer PCL1, the second conductive layer CL2, and the first conductive layer CL1 may be sequentially removed. For example, a portion of the first preliminary thickness compensation layer PCL1 may be removed first through an etching process, a portion of the second conductive layer CL2 may be removed, and then a portion of the first conductive layer CL1.

However, the formation process and sequence of the first, second, third, and fourth thickness compensation layers TL1, TL2, TL3, and TL4 according to the embodiments of the present disclosure are not limited thereto. In an embodiment, the first thickness compensation layer TL1 may be formed in the first light-emitting area LA1 on the second conductive layer CL2. After forming the first thickness compensation layer TL1, the preliminary thickness compensation layer may be formed across the first, second, and third light-emitting areas LA1, LA2, and LA3, and the non-light-emitting area NLA. After the preliminary thickness compensation layer is formed, the second thickness compensation layer TL2 is formed in the first light-emitting area LA1 by patterning the preliminary thickness compensation layer. In addition, the preliminary thickness compensation layer may be patterned, such that the third thickness compensation layer TL3 is formed in the second light-emitting area LA2 and the fourth thickness compensation layer TL4 is formed in the third light-emitting area LA3.

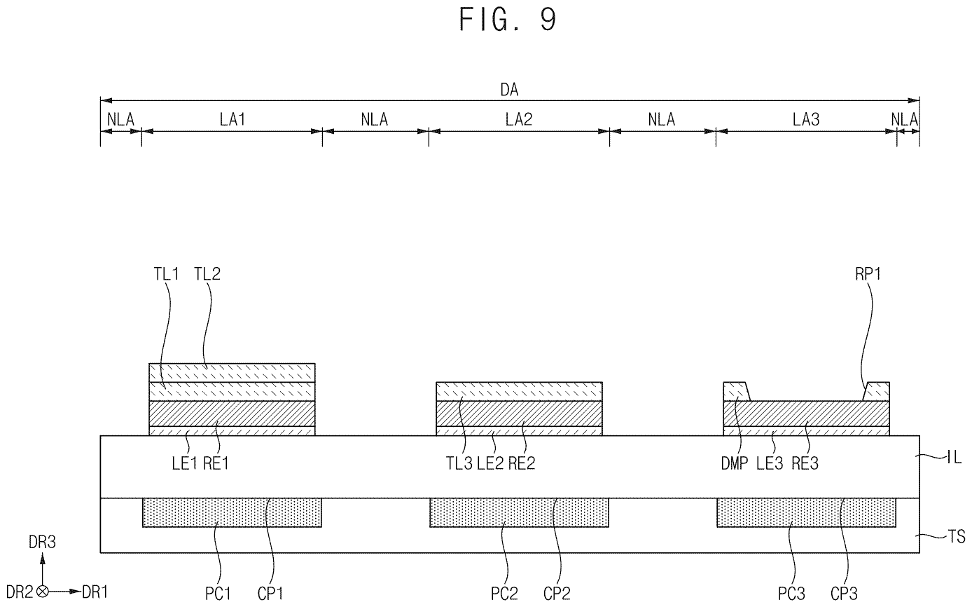

Referring to FIGS. 8 and 9, a portion of the fourth thickness compensation layer TL4 may be removed to form the dummy pattern DMP. In more detail, in the third light-emitting area LA3, the central portion of the fourth thickness compensation layer TL4 may be removed, while its edge portion remains, thereby forming the dummy pattern DMP on the third reflective electrode RE3.

By removing the central portion of the fourth thickness compensation layer TL4, a first recess RP1 that exposes the upper surface of the third reflective electrode RE3 may be formed in the dummy pattern DMP. For example, the first recess RP1 may extend to the upper surface of the third reflective electrode RE3. The first recess RP1 may face in a direction opposite to the third direction DR3, and may have a recessed shape in a cross-section.

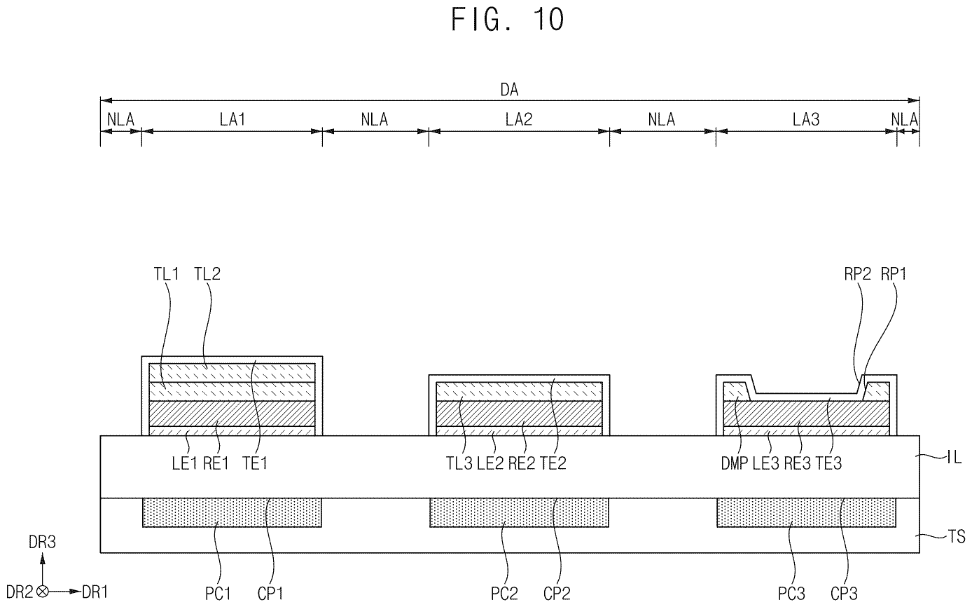

Referring to FIG. 10, a first transparent electrode TE1 may be formed in the first light-emitting area LA1. For example, the first transparent electrode TE1 may be formed on the upper surface and the side surfaces of the second thickness compensation layer TL2, the side surfaces of the first thickness compensation layer TL1, the side surfaces of the first reflective electrode RE1, and the side surfaces of the first lower electrode LE1. In more detail, the first transparent electrode TE1 may extend from the upper surface of the second thickness compensation layer TL2 along the side surfaces of the second thickness compensation layer TL2, the first thickness compensation layer TL1, the first reflective electrode RE1, and the first lower electrode LE1.

A second transparent electrode TE2 may be formed in the second light-emitting area LA2. For example, the second transparent electrode TE2 may be formed on the upper surface and the side surface of the third thickness compensation layer TL3, and the side surfaces of the second reflective electrode RE2 and the second lower electrode LE2. In more detail, the second transparent electrode TE2 may extend from the upper surface of the third thickness compensation layer TL3 along the side surface of the third thickness compensation layer TL3, the side surface of the second reflective electrode RE2, and the side surface of the second lower electrode LE2.

A third transparent electrode TE3 may be formed in the third light-emitting area LA3. For example, the third transparent electrode TE3 may be formed on the upper surface and the side surface of the dummy pattern DMP, the upper surface and the side surface of the third reflective electrode RE3, and the side surface of the third lower electrode LE3. In more detail, the third transparent electrode TE3 may extend from the upper surface of the third reflective electrode RE3 along the side and the upper surface of the dummy pattern DMP, the side surface of the third reflective electrode RE3, and the side surface of the third lower electrode LE3.

The third transparent electrode TE3 may fill the first recess RP1. In an embodiment, the third transparent electrode TE3 may have a uniform or a substantially uniform thickness in a cross-section along the profile of the third reflective electrode RE3 and the dummy pattern DMP. Accordingly, a second recess RP2 corresponding to the first recess RP1 may be formed in the third transparent electrode TE3. In more detail, the second recess RP2 may be formed in a portion of the third transparent electrode TE3 that directly contacts the upper surface of the third reflective electrode RE3. The second recess RP2 may face in the direction opposite to the third direction DR3, and may have a recessed shape in a cross-section.

Accordingly, the structures of the display device (e.g., the display device DD of FIG. 1) formed on the central portion of the third reflective electrode RE3 may have a smaller height, based on the transistor array substrate TS, than those of the structures of the display device formed on the central portion of the first reflective electrode RE1 and/or the second reflective electrode RE2. In other words, the structures of the display device formed on the central portion of the third reflective electrode RE3 may have a recessed shape in a cross-section according to the shapes of the first recess RP1 and the second recess RP2.

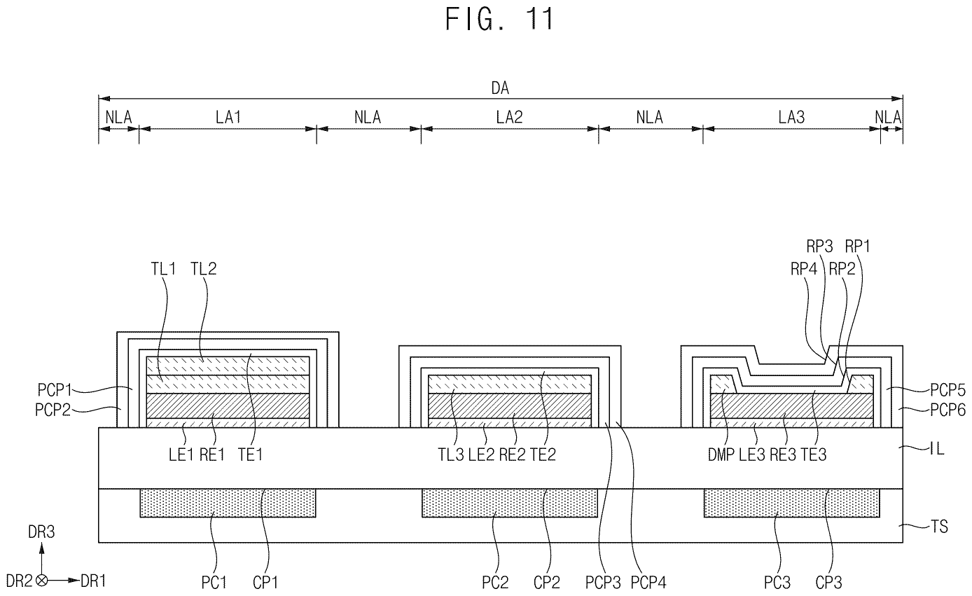

Referring to FIG. 11, in the first light-emitting area LA1, a first preliminary capping layer PCP1 may be formed on the first transparent electrode TE1. A second preliminary capping layer PCP2 may be formed on the first preliminary capping layer PCP1. In an embodiment, the first preliminary capping layer PCP1 may entirely surround (e.g., around a periphery of) an upper surface and side surfaces of the first transparent electrode TE1. In an embodiment, the second preliminary capping layer PCP2 may entirely surround (e.g., around a periphery of) the upper surface and side surfaces of the first preliminary capping layer PCP1.

In the second light-emitting area LA2, a third preliminary capping layer PCP3 may be formed on the second transparent electrode TE2. A fourth preliminary capping layer PCP4 may be formed on the third preliminary capping layer PCP3. In an embodiment, the third preliminary capping layer PCP3 may entirely surround (e.g., around a periphery of) an upper surface and side surfaces of the second transparent electrode TE2. In an embodiment, the fourth preliminary capping layer PCP4 may entirely surround (e.g., around a periphery of) the upper surface and side surfaces of the third preliminary capping layer PCP3.

In the third light-emitting area LA3, a fifth preliminary capping layer PCP5 may be formed on the third transparent electrode TE3. A sixth preliminary capping layer PCP6 may be formed on the fifth preliminary capping layer PCP5. In an embodiment, the fifth preliminary capping layer PCP5 may entirely surround (e.g., around a periphery of) an upper surface and side surfaces of the third transparent electrode TE3. In an embodiment, the sixth preliminary capping layer PCP6 may entirely surround (e.g., around a periphery of) the upper surface and side surfaces of the fifth preliminary capping layer PCP5.

In an embodiment, a third recess RP3 corresponding to the second recess RP2 may be formed in the fifth preliminary capping layer PCP5. The third recess RP3 may be defined by a portion of the fifth preliminary capping layer PCP5 recessed in correspondence with the second recess RP2.

In an embodiment, a fourth recess RP4 corresponding to the third recess RP3 may be formed in the sixth preliminary capping layer PCP6. The fourth recess RP4 may be defined by a portion of the sixth preliminary capping layer PCP6 recessed in correspondence with the third recess RP3.

In an embodiment, the first preliminary capping layer PCP1, the third preliminary capping layer PCP3, and the fifth preliminary capping layer PCP5 may include the same material as each other. For example, each of the first preliminary capping layer PCP1, the third preliminary capping layer PCP3, and the fifth preliminary capping layer PCP5 may include silicon oxide (SiOₓ).

In an embodiment, the second preliminary capping layer PCP2, the fourth preliminary capping layer PCP4, and the sixth preliminary capping layer PCP6 may include the same material as each other. For example, each of the second preliminary capping layer PCP2, the fourth preliminary capping layer PCP4, and the sixth preliminary capping layer PCP6 may include silicon nitride (SiNₓ).

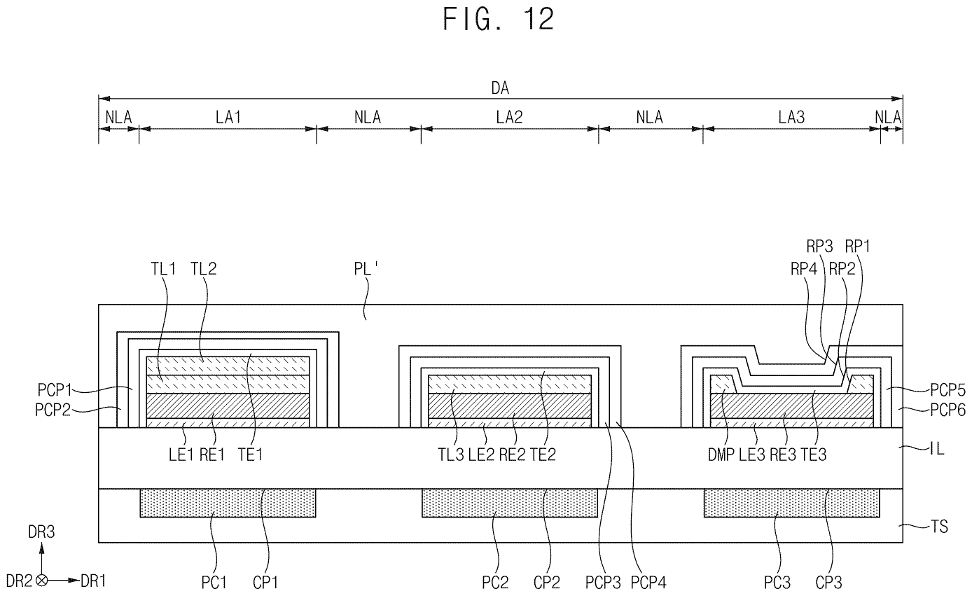

Referring to FIG. 12, a first preliminary planarization layer PL′ may be formed on the insulating structure IL. For example, the first preliminary planarization layer PL′ may be formed over the first light-emitting area LA1, the second light-emitting area LA2, the third light-emitting area LA3, and the non-light-emitting area NLA. In more detail, the first preliminary planarization layer PL′ may be formed on the second preliminary capping layer PCP2, the fourth preliminary capping layer PCP4, and the sixth preliminary capping layer PCP6.

In addition, the first preliminary planarization layer PL′ may fill an area between the second preliminary capping layer PCP2 and the fourth preliminary capping layer PCP4, an area between the fourth preliminary capping layer PCP4 and the sixth preliminary capping layer PCP6, and an area between the second preliminary capping layer PCP2 and the sixth preliminary capping layer PCP6. Accordingly, the first preliminary planarization layer PL′ may provide a flat or substantially flat top surface, and may entirely cover the second preliminary capping layer PCP2, the fourth preliminary capping layer PCP4, and the sixth preliminary capping layer PCP6. In an embodiment, the first preliminary planarization layer PL′ may include an organic insulating material.

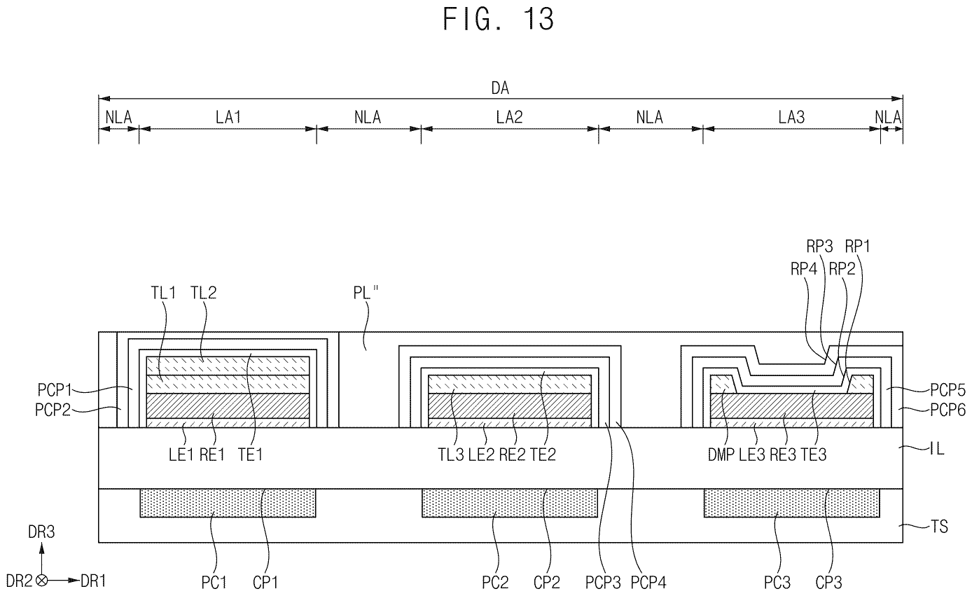

Referring to FIGS. 12 and 13, a second preliminary planarization layer PL″ may be formed by removing a portion of the first preliminary planarization layer PL′. For example, the second preliminary planarization layer PL″ may be a portion remaining after the upper portion of the first preliminary planarization layer PL′ is removed.

In an embodiment, the second preliminary planarization layer PL″′ may be formed by performing a planarization process on the upper portion of the first preliminary planarization layer PL′. For example, the planarization process may be a chemical mechanical polishing CMP process. However, the planarization process according to the embodiments of the present disclosure is not limited thereto.

In an embodiment, the planarization process may be performed on the first preliminary planarization layer PL′, such that an upper surface of the second preliminary planarization layer PL″ aligns with the upper surface of the second preliminary capping layer PCP2. In more detail, the second preliminary planarization layer PL″ may be formed by removing an upper portion of the first preliminary planarization layer PL′ so as to expose the upper surface of the second preliminary capping layer PCP2 that is covered by the first preliminary planarization layer PL′. In an embodiment, the second preliminary planarization layer PL″ may provide a flat or substantially flat upper surface.

In an embodiment, the second preliminary planarization layer PL″ may entirely cover the fourth preliminary capping layer PCP4 and the sixth preliminary capping layer PCP6. In other words, after the planarization process is completed, the upper surfaces of the fourth preliminary capping layer PCP4 and the sixth preliminary capping layer PCP6 may not be exposed.

The first preliminary planarization layer PL′ or the second preliminary planarization layer PL″ may be referred to as a preliminary planarization layer.

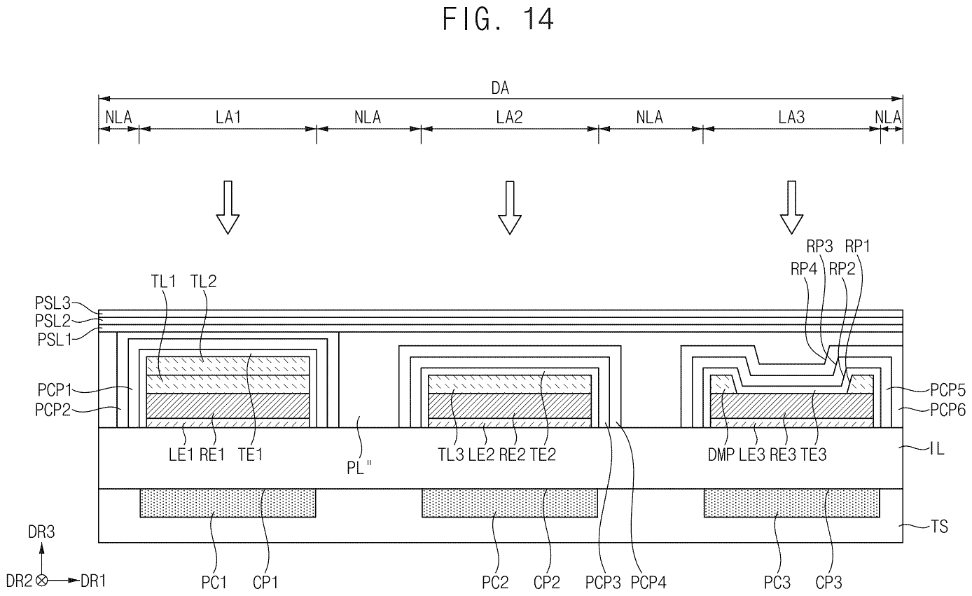

Referring to FIG. 14, a first preliminary separation layer PSL1 may be formed on the second preliminary planarization layer PL″. A second preliminary separation layer PSL2 may be formed on the first preliminary separation layer PSL1. A third preliminary separation layer PSL3 may be formed on the second preliminary separation layer PSL2. In an embodiment, the first preliminary separation layer PSL1, the second preliminary separation layer PSL2, and the third preliminary separation layer PSL3 may be formed over the first light-emitting area LA1, the second light-emitting area LA2, the third light-emitting area LA3, and the non-light-emitting area NLA.

In an embodiment, the first preliminary separation layer PSL1 and the third preliminary separation layer PSL3 may include the same material as each other. In an embodiment, the second preliminary separation layer PSL2 may include a material different from that of each of the first preliminary separation layer PSL1 and the third preliminary separation layer PSL3. For example, the first preliminary separation layer PSL1 and the third preliminary separation layer PSL3 may include silicon oxide (SiOx), and the second preliminary separation layer PSL2 may include silicon nitride (SiNx).

Referring to FIGS. 3, 14, 15, and 16, in the first light-emitting area LA1, portions of the second preliminary separation layer PSL2 and the third preliminary separation layer PSL3 may be removed to form the second layer SP1b and the third layer SP1c of the first separation structure SP1. In the second light-emitting area LA2, portions of the second preliminary separation layer PSL2 and the third preliminary separation layer PSL3 may be removed to form the second layer SP2b and the third layer SP2c of the second separation structure SP2. In the third light-emitting area LA3, portions of the second preliminary separation layer PSL2 and the third preliminary separation layer PSL3 may be removed to form the second layer SP3b and the third layer SP3c of the third separation structure SP3.

After portions of the second preliminary separation layer PSL2 and the third preliminary separation layer PSL3 are removed, a portion of the first preliminary separation layer PSL1 may also be removed. In more detail, in the first light-emitting area LA1, a portion of the first preliminary separation layer PSL1 may be removed to form the first layer SP1a of the first separation structure SP1. In the second light-emitting area LA2, a portion of the first preliminary separation layer PSL1 may be removed to form the first layer SP2a of the second separation structure SP2. In the third light-emitting area LA3, a portion of the third preliminary separation layer PSL3 may be removed to form the first layer SP3a of the third separation structure SP3. Accordingly, the first separation structure SP1 including the first layer SP1a, the second layer SP1b, and the third layer SP1c may be formed. The second separation structure SP2 including the first layer SP2a, the second layer SP2b, and the third layer SP2c may also be formed. The third separation structure SP3 including the first layer SP3a, the second layer SP3b, and the third layer SP3c may also be formed.

After a portion of the first preliminary separation layer PSL1 is removed, a portion of the second preliminary planarization layer PL″ that directly contact the removed portion of the first preliminary separation layer PSL1 may be removed. A portion of the second preliminary planarization layer PL″ may be removed to form a planarization layer PL.

After the second preliminary planarization layer PL″ is removed, in the first light-emitting area LA1, portions of the first capping layer C1 and the second capping layer C2 that overlap with the removed portion of the second preliminary planarization layer PL″ may be removed. For example, in the first light-emitting area LA1, the first capping layer C1, the second capping layer C2, and the second preliminary planarization layer PL″ may be removed to form a second-first opening OP2-1. In more detail, the first capping layer C1, the second capping layer C2, and the second preliminary planarization layer PL″ may be removed to expose an upper surface of the first transparent electrode TE1.

After the second preliminary planarization layer PL'′ is removed, in the second light-emitting area LA2, portions of the third capping layer C3 and the fourth capping layer C4 that overlap with the removed portion of the second preliminary planarization layer PL″ may be removed. For example, in the second light-emitting area LA2, the third capping layer C3, the fourth capping layer C4, and the second preliminary planarization layer PL″ may be removed to form a first-second opening OP1-2 and a second-second opening OP2-2. In more detail, the third capping layer C3, the fourth capping layer C4, and the second preliminary planarization layer PL″ may be removed to expose an upper surface of the second transparent electrode TE2.

After the second preliminary planarization layer PL″ is removed, in the third light-emitting area LA3, portions of the fifth capping layer C5 and the sixth capping layer C6 that overlap with the removed portion of the second preliminary planarization layer PL″ may be removed. For example, in the third light-emitting area LA3, the fifth capping layer C5, the sixth capping layer C6, and the second preliminary planarization layer PL″ may be removed to form a first-third opening OP1-3 and a second-third opening OP2-3. In more detail, the fifth capping layer C5, the sixth capping layer C6, and the second preliminary planarization layer PL″ may be removed to expose an upper surface of the third transparent electrode TE3.

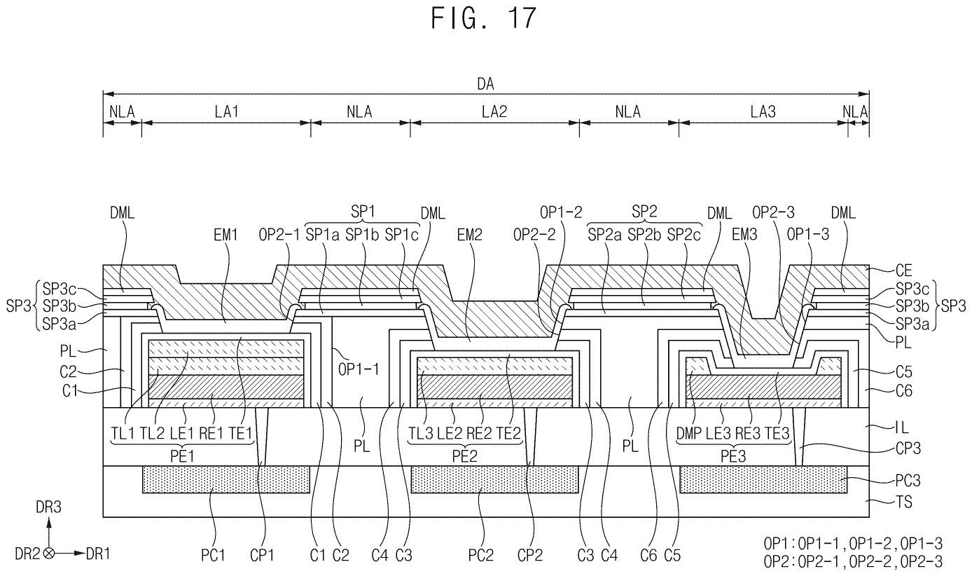

Referring to FIG. 17, the first light-emitting layer EM1 may be formed on the first transparent electrode TE1. In an embodiment, the first light-emitting layer EM1 may be formed on the upper surface of the first transparent electrode TE1 and on the side surface of the planarization layer PL defining the first-first opening OP1-1. For example, in the first light-emitting area LA1, the first light-emitting layer EM1 may be formed to fill the second-first opening OP2-1. In addition, the first light-emitting layer EM1 may extend along a side surface of the planarization layer PL defining the first-first opening OP1-1 to an upper surface of the first layer SP1a of the first separation structure SP1 and an upper surface of the first layer SP3a of the third separation structure SP3.

The second light-emitting layer EM2 may be formed on the second transparent electrode TE2. In an embodiment, the second light-emitting layer EM2 may be formed on the upper surface of the second transparent electrode TE2 and on the side surface of the planarization layer PL defining the first-second opening OP1-2. For example, in the second light-emitting area LA2, the second light-emitting layer EM2 may be formed to fill the second-second opening OP2-2. In addition, the second light-emitting layer EM2 may extend along the side surface of the planarization layer PL defining the first-second opening OP1-2 to an upper surface of the first layer SP1a of the first separation structure SP1 and an upper surface of the first layer SP2a of the second separation structure SP2.

The third light-emitting layer EM3 may be formed on the third transparent electrode TE3. In an embodiment, the third light-emitting layer EM3 may be formed on the upper surface of the third transparent electrode TE3 and on the side surface of the planarization layer PL defining the first-third opening OP1-3. For example, in the third light-emitting area LA3, the third light-emitting layer EM3 may be formed to fill the second-third opening OP2-3. In addition, the third light-emitting layer EM3 may extend along a side surface of the planarization layer PL defining the first-third opening OP1-3 to the upper surfaces of the first layer SP2a of the second separation structure SP2 and the first layer SP3a of the third separation structure SP3.

In an embodiment, the first light-emitting layer EM1, the second light-emitting layer EM2, the third light-emitting layer EM3, and dummy layers DML may be formed concurrently (e.g., simultaneously or substantially simultaneously) with each other. For example, when a light-emitting material is applied, the light-emitting material deposited in the first openings OP1 may respectively form the first light-emitting layer EM1, the second light-emitting layer EM2, and the third light-emitting layer EM3. For example, when the light-emitting material is applied, the light-emitting material deposited on the first, second, and third separation structures SP1, SP2, and SP3 may form the dummy layers DML.

In an embodiment, after the first light-emitting layer EM1, the second light-emitting layer EM2, the third light-emitting layer EM3, and the dummy layers DML are formed, a common electrode CE may be formed on the first light-emitting layer EM1, the second light-emitting layer EM2, and the third light-emitting layer EM3. In an embodiment, the common electrode CE may be formed on the first separation structure SP1, the second separation structure SP2, and the third separation structure SP3. In an embodiment, the common electrode CE may be formed over the first light-emitting area LA1, the second light-emitting area LA2, the third light-emitting area LA3, and the non-light-emitting area NLA.

As described above, in the method for manufacturing the display device according to some embodiments of the present disclosure, in the first light-emitting area LA1, preliminary thickness compensation layers (e.g., the first preliminary thickness compensation layer PCL1 and the second preliminary thickness compensation layer) may be removed, such that two thickness compensation layers (e.g., the first thickness compensation layer TL1 and the second thickness compensation layer TL2) remain. In the second light-emitting area LA2, the preliminary thickness compensation layers may be removed, such that one thickness compensation layer (e.g., the third thickness compensation layer TL3) remains. In the third light-emitting area LA3, a dummy pattern DMP in which a recess (e.g., the first recess RP1) is defined may be formed. In addition, by planarizing the organic layer (e.g., the first preliminary planarization layer PL'), a planarization layer PL having a uniform height from the transistor array substrate TS may be formed in each of the first, second, and third light-emitting areas LA1, LA2, and LA3. Accordingly, a display device DD having an improved display quality may be manufactured (e.g., may be easily manufactured), and the time and costs of a manufacturing process of the display device DD may be reduced.

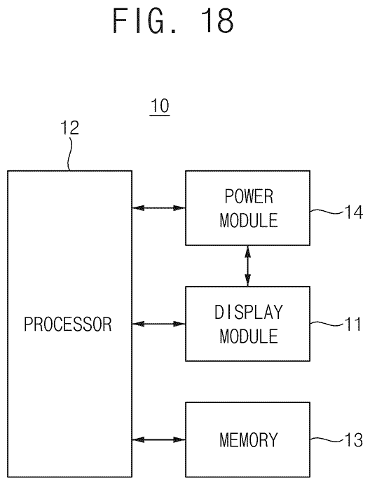

FIG. 18 is a block diagram of an electronic device according to an embodiment.

A display device (e.g., the display device DD of FIG. 1) according to an embodiment may be applied to various suitable electronic devices. An electronic device according to an embodiment includes the above-described display device, and may further include additional modules or devices having various suitable functions other than the display device.

Referring to FIG. 18, an electronic device 10 according to an embodiment may include a display module (e.g., a display or a touch-display) 11, a processor 12, a memory 13, and a power module (e.g., a power supply) 14.

The processor 12 may include at least one of a central processing unit (CPU), an application processor (AP), a graphic processing unit (GPU), a communication processor (CP), an image signal processor (ISP), and/or a controller.

The memory 13 may store data information used for the operations of the processor 12 or the display module 11. When the processor 12 executes an application stored in the memory 13, image data signals and/or input control signals may be delivered to the display module 11. The display module 11 may process the received signals, and may output image information through a display screen. For example, the display device (e.g., the display device DD of FIG. 1) including the display module 11 may process the image data signals and the input control signals to output the image information through the display screen. For example, the display device may be manufactured by the method of manufacturing the display device described above with reference to FIGS. 4, 5, 6, 7, 8, 9, 10, 11, 12, 13, 14, 15, 16, and 17. Accordingly, the electronic device 10, which includes the display device having an improved display quality and operates stably, may be provided.

The power module 14 may include a power supply module, such as a power adapter or a battery device, and a power conversion module that converts the power supplied from the power supply module into power used for operating the electronic device 10.

At least one of the components of the above-described electronic device 10 may be included in the display device according to the above-described embodiments. In addition, some of the individual modules functionally included in one module may be included in the display device, while others may be provided separately from the display device. For example, the display device may include the display module 11, and the processor 12, the memory 13, and the power module 14 may be provided as other devices within the electronic device 10, separate from the display device.

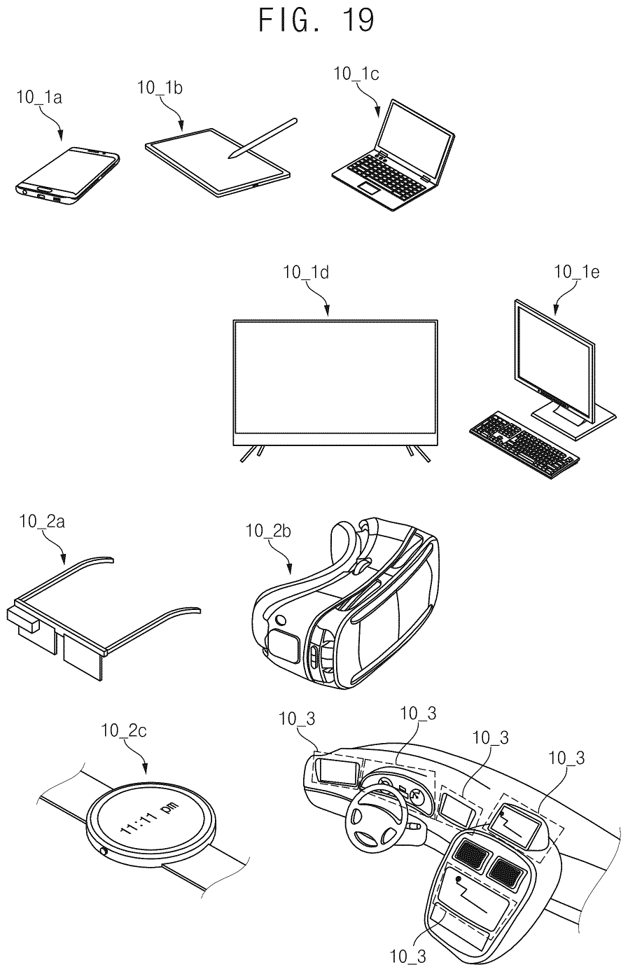

FIG. 19 is schematic diagrams of the electronic device of FIG. 18 according to some embodiments.

Referring to FIG. 19, various electronic devices to which the display device (e.g., the display device DD of FIG. 1) according to some embodiments may be applied may include not only image display electronic devices, such as a smartphone 10_1a, a tablet PC 10_1b, a laptop 10_1c, a TV 10_1d, and a desktop monitor 10_1e, but may also include wearable electronic devices including a display module, such as smart glasses 10_2a, a head-mounted display 10_2b, and a smartwatch 10_2c. They may further include vehicle electronic devices 10_3 having a display module, such as a center information display (CID) arranged on an instrument panel, a center fascia, or a dashboard of a vehicle, and a room mirror display.

The method and the device according to some embodiments described above may be applied to a display device included in a computer, a notebook, a mobile phone, a smartphone, a smart pad, a PMP, a PDA, an MP3 player, or the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in any suitable combination with each other with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a transistor array substrate comprising:
a display area comprising a first light-emitting area, a second light-emitting area, and a third light-emitting area spaced from each other; and;
a non-display area adjacent to the display area;
a first pixel electrode in the first light-emitting area on the transistor array substrate, and comprising a sequential stack of a first reflective electrode, a first thickness compensation layer, and a first transparent electrode;
a second pixel electrode in the second light-emitting area on the transistor array substrate, and comprising a sequential stack of a second reflective electrode, a second thickness compensation layer, and a second transparent electrode;
a third pixel electrode in the third light-emitting area on the transistor array substrate, and comprising a sequential stack of a third reflective electrode and a third transparent electrode;
a planarization layer having first openings overlapping with the first pixel electrode, the second pixel electrode, and the third pixel electrode;
a light-emitting layer on the first pixel electrode, the second pixel electrode, and the third pixel electrode; and
a common electrode on the light-emitting layer,
wherein a thickness of the first thickness compensation layer is greater than a thickness of the second thickness compensation layer.

2. The display device of claim 1, wherein the planarization layer comprises:
a first planarization portion located between the first pixel electrode and the second pixel electrode; and
a second planarization portion located between the second pixel electrode and the third pixel electrode, and
wherein the first planarization portion and the second planarization portion have an equal height as each other.

3. The display device of claim 1, wherein the first thickness compensation layer comprises a sequential stack of a first-first thickness compensation layer and a first-second thickness compensation layer, and
wherein a thickness of one compensation layer among the first-first thickness compensation layer or the first-second thickness compensation layer is equal to a thickness of the second thickness compensation layer.

4. The display device of claim 3, wherein the first-first thickness compensation layer and the first-second thickness compensation layer include a same material as each other.

5. The display device of claim 3, wherein the first-first thickness compensation layer and the first-second thickness compensation layer include a different material from each other.

6. The display device of claim 1, wherein the third pixel electrode further comprises:
a dummy pattern on an edge portion of the third reflective electrode between the third reflective electrode and the third transparent electrode.

7. The display device of claim 6, wherein a thickness of the dummy pattern and a thickness of the second thickness compensation layer are equal to each other.

8. The display device of claim 1, wherein the first thickness compensation layer comprises at least one selected from an oxide group consisting of a silicon oxide (SiOₓ), a silicon nitride (SiNₓ), a silicon oxynitride (SiOₓN_{y}), an aluminum oxide (Al₂O₃), a titanium oxide (TiO₂), a tantalum oxide (Ta₂O₅), a hafnium oxide (HfO₂), a zinc oxide (ZrO₂), a TEOS (tetraethyl orthosilicate), and a FTEOS (fluorinate tetraethyl orthosilicate).

9. The display device of claim 1, wherein the first transparent electrode covers an upper surface of the first thickness compensation layer, a side surface of the first thickness compensation layer, and a side surface of the first reflective electrode, and
wherein the second transparent electrode covers an upper surface of the second thickness compensation layer, a side surface of the second thickness compensation layer, and a side surface of the second reflective electrode.

10. The display device of claim 1, wherein a center portion of an upper surface of the first transparent electrode has a first height with respect to the transistor array substrate,
a center portion of an upper surface of the second transparent electrode has a second height less than the first height with respect to the transistor array substrate, and
a center portion of an upper surface of the third transparent electrode has a third height less than the second height with respect to the transistor array substrate.

11. The display device of claim 1, further comprising:
a capping structure surrounding around the first pixel electrode, the second pixel electrode, and third pixel electrode between the first pixel electrode, the second pixel electrode, and the third pixel electrode and the planarization layer,
wherein second openings overlapping with first pixel electrode, the second pixel electrode, and the third pixel electrode penetrate the capping structure.

12. The display device of claim 11, wherein the third pixel electrode further comprises:
a dummy pattern at an edge portion of the third reflective electrode between the third reflective electrode and the third transparent electrode, and
wherein the dummy pattern does not overlap with the second openings.

13. The display device of claim 12, wherein a first distance between the first reflective electrode and the common electrode is greater than a second distance between the second reflective electrode and the common electrode, and
wherein the second distance is greater than a third distance between the third reflective electrode and the common electrode.

14. A method of manufacturing a display device, the method comprising:
providing a transistor array substrate comprising:
a display area comprising a first light-emitting area, a second light-emitting area, and a third light-emitting area spaced from each other; and
a non-display area adjacent to the display area;
forming a first reflective electrode, a second reflective electrode, and a third reflective electrode in the first light-emitting area, the second light-emitting area, and third light-emitting area on the transistor array substrate, respectively;
forming a first thickness compensation layer and a second thickness compensation layer in the first light-emitting area and second light-emitting area, respectively, on the first reflective electrode and the second reflective electrode;
forming a first transparent electrode on the first thickness compensation layer in the first light-emitting area;
forming a second transparent electrode on the second thickness compensation layer in the second light-emitting area;
forming a third transparent electrode on the third reflective electrode in the third light-emitting area;
forming a planarization layer having openings overlapping with the first transparent electrode, the second transparent electrode, and third transparent electrode on the transistor array substrate;
forming a light-emitting layer in the first light-emitting area, the second light-emitting area, and the third light-emitting area on the first transparent electrode, the second transparent electrode, and the third transparent electrode; and
forming a common electrode in the first light-emitting area, the second light-emitting area, and the third light-emitting area on the light-emitting layer,
wherein a thickness of the first thickness compensation layer is greater than a thickness of the second thickness compensation layer.

15. The method of claim 14, wherein the forming of the first thickness compensation layer and the second thickness compensation layer comprises:
forming a reflective electrode layer on the transistor array substrate;
forming a preliminary thickness compensation layer in the first light-emitting area, the second light-emitting area, and the third light-emitting area on the reflective electrode layer; and
forming the second thickness compensation layer in the second light-emitting area by removing a portion of the preliminary thickness compensation layer.

16. The method of claim 15, wherein the first thickness compensation layer comprises a first-first thickness compensation layer and a first-second thickness compensation layer sequentially stacked, and
wherein the forming of the first thickness compensation layer and the second thickness compensation layer comprises:
forming the first-second thickness compensation layer on the preliminary thickness compensation layer in the first light-emitting area; and
forming the first-first thickness compensation layer under the first-second thickness compensation layer by removing the portion of the preliminary thickness compensation layer.

17. The method of claim 15, wherein the first thickness compensation layer comprises a first-first thickness compensation layer and a first-second thickness compensation layer sequentially stacked, and
wherein the forming of the first thickness compensation layer and the second thickness compensation layer comprises:
forming the first-first thickness compensation layer in the first light-emitting area on the reflective electrode layer before forming the preliminary thickness compensation layer; and
forming the first-second thickness compensation layer on the first-first thickness compensation layer by removing the portion of the preliminary thickness compensation layer.

18. The method of claim 15, wherein the forming of the third transparent electrode comprises:
forming a third thickness compensation layer on the third reflective electrode by removing the portion of the preliminary thickness compensation layer;
forming a dummy pattern at an edge portion of the third reflective electrode by removing a portion of the third thickness compensation layer; and
forming the third transparent electrode surrounding around the third reflective electrode and the dummy pattern.

19. The method of claim 14, wherein the forming of the planarization layer comprises:
forming a first capping structure covering the first transparent electrode;
forming a second capping structure covering the second transparent electrode;
forming a third capping structure covering the third transparent electrode;
forming a preliminary planarization layer on the first capping structure, the second capping structure, and the third capping structure;
exposing an upper surface of the first capping structure by planarizing the preliminary planarization layer; and
forming the openings overlapping with the first transparent electrode, the second transparent electrode, and the third transparent electrode in the preliminary planarization layer.

20. An electronic device comprising:
a processor configured to output an image data signal and an input control signal; and
a display device configured to process the image data signal and the input control signal to output image information through a display screen, the display device comprising:
a transistor array substrate comprising:
a display area comprising:
a first light-emitting area, a second light-emitting area, and
a third light-emitting area spaced from each other; and
a non-display area adjacent to the display area;
a first pixel electrode in the first light-emitting area on the transistor array substrate, and comprising a sequential stack of a first reflective electrode, a first thickness compensation layer, and a first transparent electrode;
a second pixel electrode in the second light-emitting area on the transistor array substrate, and comprising a sequential stack of a second reflective electrode, a second thickness compensation layer, and a second transparent electrode;
a third pixel electrode in the third light-emitting area on the transistor array substrate, and comprising a sequential stack of a third reflective electrode and a third transparent electrode;
a planarization layer having first openings overlapping with the first pixel electrode, the second pixel electrode, and the third pixel electrode;
a light-emitting layer on the first pixel electrode, the second pixel electrode, and the third pixel electrode; and
a common electrode on the light-emitting layer,
wherein a thickness of the first thickness compensation layer is greater than a thickness of the second thickness compensation layer.
